(19) United States
(12) Patent Application Publication
(10) Pub. No.: US 2026/0215136 A1
(43) Pub. Date: Jul. 23, 2026

(54) DISPLAY DEVICE AND ELECTRONIC DEVICE INCLUDING THE SAME

(71) Applicant: Samsung Display Co., Ltd., Yongin-si (KR)

(72) Inventors: Hyo Joon KIM, Yongin-si (KR); Soon Gi PARK, Yongin-si (KR); Ju Youn SON, Yongin-si (KR); Ju Hwa HA, Yongin-si (KR)

(21) Appl. No.: 19/391,287

(22) Filed: Nov. 17, 2025

(30) Foreign Application Priority Data
Jan. 21, 2025 (KR) 10-2025-0008813

(51) Int. Cl. H10K 59/80

(52) U.S. Cl. CPC H10K 59/878; H10K 59/879

(57) ABSTRACT

A display device and an electronic device including the display device are provided. The display device includes: a display panel; a first polarizing film located on the display panel; a first phase retardation film located on the first polarizing film; a reflection control film located on the first phase retardation film; a first lens located on the reflection control film; a second lens located on the first lens; a second phase retardation film located on the second lens; a second polarizing film located on the second phase retardation film; and a third lens located on the second polarizing film, wherein the reflection control film includes a first portion and a second portion located at a periphery of the first portion, and a reflectivity of the first portion is different from a reflectivity of the second portion.

### CROSS-REFERENCE TO RELATED APPLICATION

The present application claims priority to and the benefit of Korean Patent Application No. 10-2025-0008813, filed on Jan. 21, 2025, in the Korean Intellectual Property Office, the entire content of which is incorporated herein by reference.

### BACKGROUND

### 1. Field

One or more embodiments of the present disclosure relate to a display device and an electronic device including the same.

### 2. Description of the Related Art

A head mounted display (HMD) is an image display device that is worn on a user's head, in the form of glasses or helmets, to form focus at a close distance in front of the user's eyes (e.g., to present images at the close distance in front of the user's eyes). Head mounted displays may be used to implement virtual reality (VR) or augmented reality (AR) experiences.

A head mounted display magnifies an image displayed on a small display device by utilizing a plurality of lenses, thereby displaying (presenting) the magnified image to a user. Therefore, the display device (e.g., a display panel) applied to the head mounted display may need to provide high-resolution images, for example, images with a resolution of 3000 pixels per inch (PPI) or higher. To meet this requirement or desire, an organic light emitting diode on silicon (OLEDoS) display—a high-resolution, small-form-factor organic light-emitting display—may be employed. OLEDoS refers to a display device in which an organic light emitting diode (OLED) is formed on a semiconductor wafer substrate that includes complementary metal oxide semiconductor (CMOS) circuitry.

### SUMMARY

One or more aspects of embodiments of the present disclosure are directed toward a display device with a minimized or reduced thickness of an optical module.

One or more aspects of embodiments of the present disclosure are directed toward a display device with improved light output efficiency.

However, aspects of the present disclosure are not restricted to those set forth herein. The above and other aspects of the present disclosure will become more apparent to one of ordinary skill in the art to which the present disclosure pertains by referencing the detailed description of the present disclosure provided herein or by practice of the presented embodiments of the disclosure.

According to one or more embodiments of the present disclosure, a display device includes: a display panel; a first polarizing film on (e.g., located on) the display panel, a first phase retardation film on (e.g., located on) the first polarizing film, a reflection control film on (e.g., located on) the first phase retardation film, a first lens on (e.g., located on) the reflection control film, a second lens on (e.g., located on) the first lens, a second phase retardation film on (e.g., located on) the second lens, a second polarizing film on (e.g., located on) the second phase retardation film, and a third lens on (e.g., located on) the second polarizing film, wherein the reflection control film includes a first portion and a second portion located at a periphery of the first portion, and a reflectivity of the first portion is different from a reflectivity of the second portion.

In one or more embodiments, the reflectivity of the second portion is greater than the reflectivity of the first portion.

In one or more embodiments, the reflectivity of the first portion is about 47% to about 53%, and the reflectivity of the second portion is about 80% or more.

In one or more embodiments, the first portion includes a half mirror, and the second portion includes a regular mirror.

In one or more embodiments, the first portion includes multilayer films in which low-refractive index films and high-refractive index films are alternately stacked.

In one or more embodiments, the low-refractive index film includes (e.g., contains) at least one of silicon oxide or silicon oxynitride.

In one or more embodiments, the high-refractive index film includes (e.g., contains) at least one of silicon nitride or titanium oxide.

In one or more embodiments, the second portion includes a substrate and a reflective layer including a metal material.

In one or more embodiments, the first portion is configured to transmit and reflect light generated from the display panel, and the second portion is configured to reflect light generated from the display panel.

In one or more embodiments, the first lens, the second lens, and the third lens are spaced and/or apart (e.g., spaced apart or separated) from each other.

In one or more embodiments, the display device may further include at least one anti-reflection coating film located between the first lens and the second lens, and/or between the second lens and the third lens. For example, the display device may further include at least one anti-reflection coating film between the first lens and the second lens, and at least one anti-reflection coating film between the second lens and the third lens. For example, the display device may include a first anti-reflection coating film positioned between the first and second lenses, and/or a second anti-reflection coating film positioned between the second and third lenses.

In one or more embodiments, the first lens, the second lens, and the third lens are combined to form a triplet lens.

In one or more embodiments, the display device may further include a first adhesive layer between (e.g., located between) the first lens and the second lens, and a second adhesive layer between (e.g., located between) the second lens and the third lens.

In one or more embodiments, the first lens and the second lens are combined to form a doublet lens, and the doublet lens and the third lens are spaced and/or apart (e.g., spaced apart or separated) from each other.

In one or more embodiments, the display device may further include an adhesive layer between (e.g., located between) the first lens and the second lens, and at least one anti-reflection coating film between (e.g., located between) the doublet lens and the third lens.

In one or more embodiments, the second lens and the third lens are combined to form a doublet lens, and the doublet lens and the first lens are spaced and/or apart (e.g., spaced apart or separated) from each other.

In one or more embodiments, the display device may further include an adhesive layer between (e.g., located between) the second lens and the third lens, and at least one anti-reflection coating film between (e.g., located between) the doublet lens and the first lens.

In one or more embodiments, the reflection control film is on (e.g., located on) a first surface of the first lens, and the first surface of the first lens is an aspherical surface.

In one or more embodiments, each of the first lens, the second lens, and the third lens is a magnifying lens.

According to one or more embodiments of the present disclosure, an electronic device includes a display device and a processor providing a signal to the display device, wherein the display device includes: a display panel; a first polarizing film on (e.g., located on) the display panel; a first phase retardation film on (e.g., located on) the first polarizing film; a reflection control film on (e.g., located on) the first phase retardation film; a first lens on (e.g., located on) the reflection control film; a second lens on (e.g., located on) the first lens; a second phase retardation film on (e.g., located on) the second lens; a second polarizing film on (e.g., located on) the second phase retardation film; and a third lens on (e.g., located on) the second polarizing film, wherein the reflection control film includes a first portion and a second portion located at a periphery of the first portion, and a reflectivity of the first portion is different from a reflectivity of the second portion.

In accordance with the display device according to one or more embodiments of the present disclosure, the thickness of the optical module thereof may be minimized or reduced.

In accordance with the display device according to one or more embodiments of the present disclosure, the light output efficiency of the display device may be improved.

For example, the present disclosure provides a display device and an electronic device including the same, which are capable of achieving both a compact optical module structure and enhanced light output efficiency. By incorporating a reflection control film with region-specific reflectivity, a multilayer lens system, and optional anti-reflection and adhesive layers, the disclosed configuration enables high-resolution image display suitable for head-mounted applications such as VR and/or AR. These and other features described herein contribute to improved visual performance and user experience while supporting lighter, thinner, and/or more efficient wearable display technologies.

It should be noted that effects and aspects of the present disclosure are not limited to those described above and other effects and aspects of the present disclosure will be apparent to those skilled in the art from the following descriptions.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects and features of the present disclosure will become more apparent and appreciated from the following descriptions of example embodiments thereof with reference to the accompanying drawings, in which:

FIG. 1 is an exploded perspective view showing a display device according to one or more embodiments of the present disclosure;

FIG. 2 is a block diagram illustrating an example of the display panel shown in FIG. 1 according to one or more embodiments of the present disclosure;

FIG. 3 is an equivalent circuit diagram of a first sub-pixel according to one or more embodiments of the present disclosure;

FIG. 4 is a layout diagram illustrating an example of a display panel according to one or more embodiments of the present disclosure;

FIG. 5 is a layout diagram showing an example of the display area of FIG. 4 according to one or more embodiments of the present disclosure;

FIG. 6 is a layout diagram showing an example of the display area of FIG. 4 according to one or more embodiments of the present disclosure;

FIG. 7 is a cross-sectional view illustrating an example of a display panel taken along the line I1-I1′ of FIG. 5 according to one or more embodiments of the present disclosure;

FIG. 8 is a cross-sectional view illustrating an example of a display panel taken along the line I1-I1′ of FIG. 5 according to one or more embodiments of the present disclosure;

FIG. 9 is a schematic cross-sectional view illustrating a display element layer, lenses, and an optical module of a display device according to one or more embodiments of the present disclosure;

FIGS. 10 and 11 are cross-sectional views showing a display device according to one or more embodiments of the present disclosure;

FIG. 12 is a plan view showing a reflection control film according to one or more embodiments of the present disclosure;

FIG. 13 is a graph showing reflectivity of a reflection control film according to one or more embodiments of the present disclosure;

FIG. 14 is a schematic diagram illustrating the path and polarization state of light emitted from a display device according to one or more embodiments of the present disclosure;

FIGS. 15 and 16 are cross-sectional views showing a display device according to one or more embodiments of the present disclosure;

FIGS. 17 and 18 are cross-sectional views showing a display device according to one or more embodiments of the present disclosure;

FIGS. 19 and 20 are cross-sectional views showing a display device according to one or more embodiments of the present disclosure;

FIG. 21 is an exploded perspective view illustrating a head mounted display according to one or more embodiments of the present disclosure;

FIG. 22 is a perspective view showing an augmented reality content providing device according to one or more embodiments of the present disclosure;

FIG. 23 is a rear exploded perspective view of the augmented reality content providing device of FIG. 22 according to one or more embodiments of the present disclosure;

FIG. 24 is a front exploded perspective view of the augmented reality content providing device of FIG. 22 according to one or more embodiments of the present disclosure;

FIG. 25 is a block diagram of an electronic device according to one or more embodiments of the present disclosure; and

FIG. 26 is a schematic view illustrating electronic devices according to various embodiments of the present disclosure.

### DETAILED DESCRIPTION

The disclosure will now be described more fully hereinafter with reference to the accompanying drawings, in which example embodiments of the present disclosure are shown. This disclosure may, however, be embodied in different forms and should not be construed as limited to one or more embodiments set forth herein. Rather, these embodiments are provided so that this disclosure will be thorough and complete, and will fully convey the scope of the present disclosure to those skilled in the art.

It will also be understood that if (e.g., when) a layer is referred to as being “on” another layer or substrate, it may be directly on the other layer or substrate, or one or more intervening layers or an air gap may also be present therebetween. In contrast, “directly on” may refer to that there are no additional intervening elements or layers between the element or layer and the another element or layer. Furthermore, in one or more embodiments of the present disclosure, if (e.g., when) an element is referred to as being arranged “on” another element, it may be arranged “above” the other element or arranged “under” or “below” the other element. The same or like reference numbers indicate the same or like components throughout the disclosure.

Hereinafter, one or more embodiments of the present disclosure will be described in more detail with reference to the accompanying drawings.

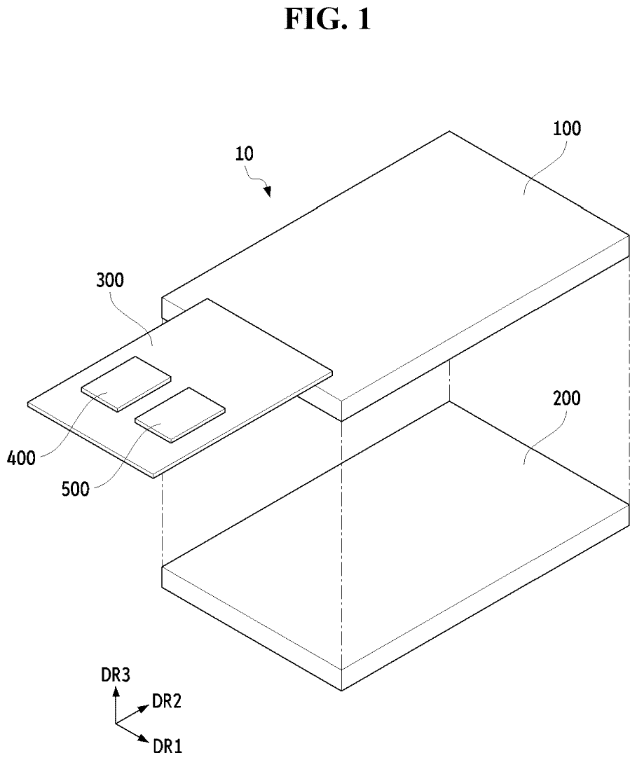

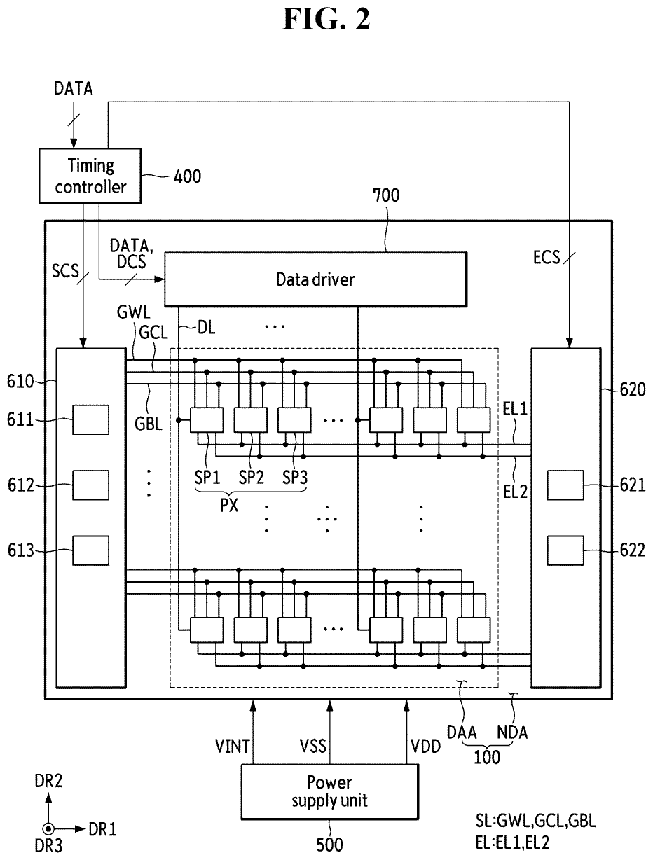

FIG. 1 is an exploded perspective view showing a display device according to one or more embodiments of the present disclosure. FIG. 2 is a block diagram illustrating an example of the display panel shown in FIG. 1 according to one or more embodiments.

Referring to FIG. 1 and FIG. 2, a display device 10 according to one or more embodiments is a device displaying a moving image or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) and/or the like. For example, the display device 10 according to one or more embodiments may be applied as a display unit of a television, a laptop, a monitor, a billboard, or an Internet-of-Things (IoT) terminal. In one or more embodiments, the display device 10 may be applied to a smart watch, a watch phone, a head mounted display (HMD) for implementing virtual reality and/or augmented reality, and/or the like.

The display device 10 according to one or more embodiments includes a display panel 100, a heat dissipation layer 200, a circuit board 300, a timing control circuit 400, and a power supply circuit 500.

In one or more embodiments, the display panel 100 may have a planar shape, for example, similar to a quadrilateral shape. For example, the display panel 100 may have a planar shape, similar to a quadrilateral shape, that has a short side of a first direction DR1 and a long side of a second direction DR2 intersecting the first direction DR1. In the display panel 100, a corner where the short side in the first direction DR1 and the long side in the second direction DR2 meet may be right-angled or rounded with a selected or set curvature. The planar shape of the display panel 100 is not limited to a quadrilateral shape, and may be a shape similar to another polygonal shape, a circular shape, or an elliptical shape. A planar shape of the display device 10 may conform to the planar shape of the display panel 100, but embodiments of the present disclosure are not limited thereto.

In the illustrated drawings, the first direction DR1 and the second direction DR2 cross each other as horizontal directions. For example, in one or more embodiments, the first direction DR1 and the second direction DR2 may be orthogonal to each other. In addition, a third direction DR3 crosses the first direction DR1 and the second direction DR2, and may be, for example, a direction orthogonal to each of the first direction DR1 and the second direction DR2, for example, may be a thickness direction of the display device. Unless otherwise defined, in the present disclosure, directions indicated by arrows of the first to third directions DR1, DR2, and DR3 may be referred to as one side of a specified direction, and the opposite directions thereto may be referred to as the other side. Also, the terms “above,” “upper side,” “upper portion,” “top,” and/or “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 2.

The plurality of pixels PX may be arranged in the display area DAA. In one or more embodiments, the plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL includes a plurality of write scan lines GWL, a plurality of control scan lines GCL, and a plurality of bias scan lines GBL. The plurality of emission control lines EL includes a plurality of first emission control lines EL1 and a plurality of second emission control lines EL2.

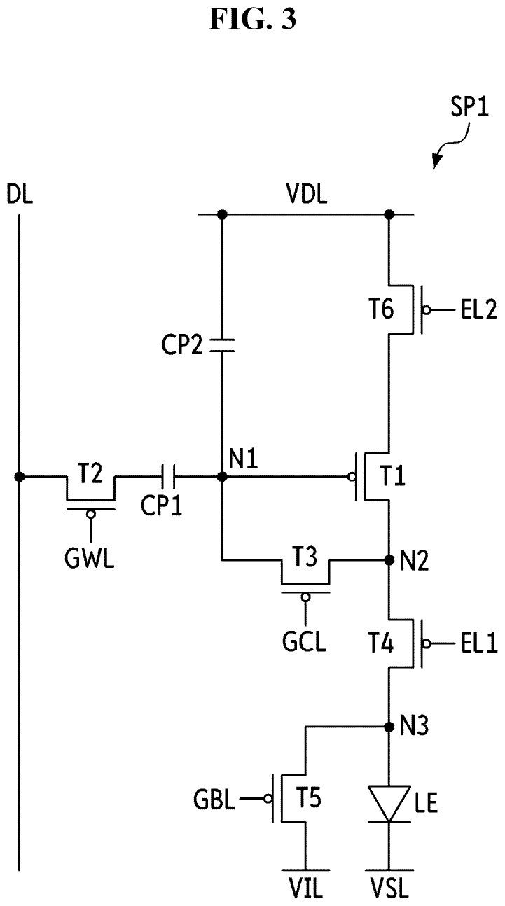

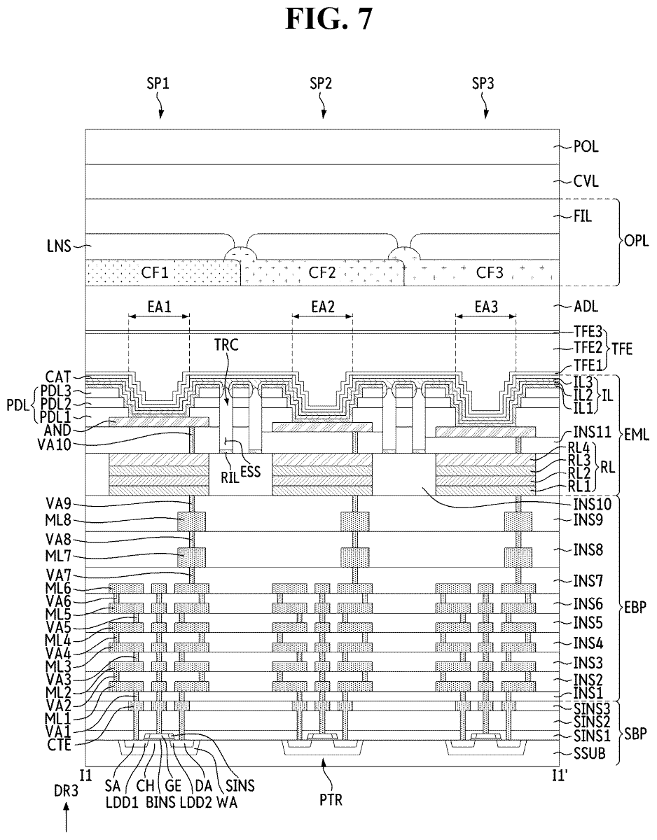

The plurality of pixels PX include a plurality of sub-pixels SP1, SP2, and SP3. The plurality of sub-pixels SP1, SP2, and SP3 may each include a plurality of pixel transistors as shown in FIG. 3, and the plurality of pixel transistors may be formed by a semiconductor process and located on a semiconductor substrate SSUB (see FIG. 7). For example, in one or more embodiments, the plurality of pixel transistors of the data driver 700 may be formed as complementary metal oxide semiconductor (CMOS) transistors, but embodiments of the present disclosure are not limited thereto.

Each of the plurality of sub-pixels SP1, SP2, and SP3 may be connected to a (e.g., one) write scan line GWL, a (e.g., one) control scan line GCL, a (e.g., one) bias scan line GBL, a (e.g., one) first emission control line EL1, a (e.g., one) second emission control line EL2, and a (e.g., one) data line DL. Each of the plurality of sub-pixels SP1, SP2, and SP3 may receive a data voltage of the data line DL in response to a write scan signal of the write scan line GWL, and emit light from a light emitting element according to the data voltage.

In one or more embodiments, the scan driver 610, the emission driver 620, and the data driver 700 may each be located in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 7) through a semiconductor process. For example, in one or more embodiments, the plurality of scan transistors and the plurality of light emitting transistors may be formed as CMOS transistors, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit (also referred as a timing controller) 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, in one or more embodiments, the plurality of data transistors may be formed as CMOS transistors, but embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to data lines DL. In this regard, the sub-pixels SP1, SP2, and SP3 may be selected by the write scan signal of the scan driver 610, and data voltages (e.g., analog data voltages) may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be located on a (e.g., one) surface, e.g., the rear surface, of the display panel 100. The heat dissipation layer 200 serves to dissipate heat generated from the display panel 100. The heat dissipation layer 200 may include a metal layer having high thermal conductivity, such as graphite, silver (Ag), copper (Cu), and/or aluminum (Al).

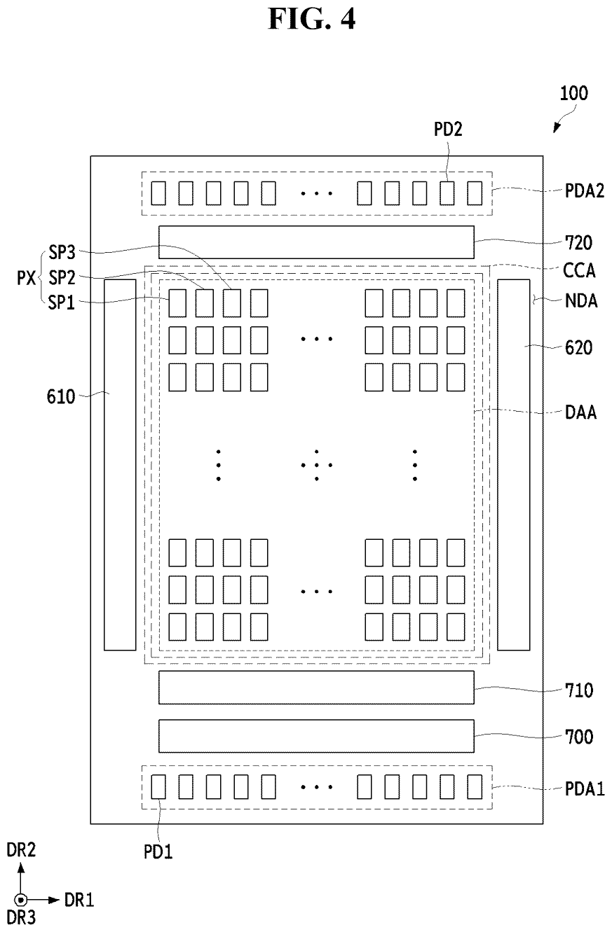

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. In one or more embodiments, the circuit board 300 may be a flexible printed circuit board with a flexible material, or a flexible film. Although the circuit board 300 is illustrated in FIG. 1 as being unfolded, the circuit board 300 may be bent. In this regard, one end of the circuit board 300 may be located on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. The one end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

The power supply circuit (also referred as power supply unit) 500 may generate a plurality of panel driving voltages according to a power voltage from the outside. For example, in one or more embodiments, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described in more detail later in conjunction with FIG. 3.

Each of the timing control circuit 400 and the power supply circuit 500 may be formed as an integrated circuit (IC) and attached to one surface of the circuit board 300. In this regard, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be located in the non-display area NDA of the display panel 100, similarly to the scan driver 610, the emission driver 620, and the data driver 700. In these embodiments, the timing control circuit 400 may include a plurality of timing transistors, and the power supply circuit 500 may include a plurality of power transistors. The plurality of timing transistors and the plurality of power transistors may be formed on the semiconductor substrate SSUB (see FIG. 7) through a semiconductor process. For example, in one or more embodiments, the plurality of timing transistors and the plurality of power transistors may be formed as CMOS transistors, but embodiments of the present disclosure are not limited thereto. In one or more embodiments, each of the timing control circuit 400 and the power supply circuit 500 may be located between the data driver 700 and the first pad portion PDA1 (see FIG. 4).

FIG. 3 is an equivalent circuit diagram of a first sub-pixel according to one or more embodiments of the present disclosure.

Referring to FIG. 3, a first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

In one or more embodiments, the first sub-pixel SP1 includes a plurality of transistors T1 to T6, a light emitting element LE, a first capacitor CP1, and a second capacitor CP2.

The light emitting element LE emits light in response to a driving current flowing through the channel of a first transistor T1. The emission amount (e.g., emission intensity) of the light emitting element LE may be proportional to the driving current. A first electrode of the light emitting element LE may be an anode electrode, and a second electrode of the light emitting element LE may be a cathode electrode. In one or more embodiments, the light emitting element LE may be an organic light emitting diode including a first electrode, a second electrode, and an organic light emitting layer located between the first electrode and the second electrode, but embodiments of the present disclosure are not limited thereto. For example, in one or more embodiments, the light emitting element LE may be an inorganic light emitting element including a first electrode, a second electrode, and an inorganic semiconductor located between the first electrode and the second electrode, in these embodiments, the light emitting element LE may be a micro light emitting diode.

The first transistor T1 may be a driving transistor that controls a source-drain current (hereinafter referred to as “driving current”) flowing between a source electrode and a drain electrode thereof according to a voltage applied to a gate electrode thereof.

A second transistor T2 may be located between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be located between a first node N1 and a second node N2. The third transistor T3 is turned on by the write control signal of the control scan line GCL to connect the first node N1 to the second node N2. For this reason, if (e.g., when) the gate electrode and the drain electrode of the first transistor T1 are connected, the first transistor T1 may operate like a diode.

A fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light emitting element LE. A fifth transistor T5 may be located between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

A sixth transistor T6 may be located between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and a drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, in one or more embodiments, each of the first to sixth transistors T1 to T6 may be a P-type (kind) MOSFET, but embodiments of the present disclosure are not limited thereto. In one or more embodiments, each of the first to sixth transistors T1 to T6 may be an N-type (kind) MOSFET. In one or more embodiments, some of the first to sixth transistors T1 to T6 may be P-type (kind) MOSFETs, and each of the remaining transistors may be an N-type (kind) MOSFET.

Although it is illustrated in FIG. 3 that the first sub-pixel SP1 includes six transistors T1 to T6 and two capacitors CP1 and CP2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may each be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel according to one or more embodiments of the present disclosure.

Referring to FIG. 4, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be located on a first side of the display area DAA, and the emission driver 620 may be located on a second side of the display area DAA. For example, in one or more embodiments, the scan driver 610 may be located on one side of the display area DAA in the first direction DR1, and the emission driver 620 may be located on the other side of the display area DAA in the first direction DR1. However, embodiments of the present disclosure are not limited thereto, for example, in one or more embodiments, the scan driver 610 and the emission driver 620 may be located on both (e.g., simultaneously) the first side and the second side of the display area DAA.

The first pad portion PDA1 may include the plurality of first pads PD1 connected to pads or bumps of the circuit board 300 through a conductive adhesive member. The first pad portion PDA1 may be located on a third side of the display area DAA. For example, in one or more embodiments, the first pad portion PDA1 may be located on one side of the display area DAA in the second direction DR2. The first pad portion PDA1 may be located outside the data driver 700 in the second direction DR2. For example, the first pad portion PDA1 may be arranged closer to an edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board including a rigid material or a flexible printed circuit board including a flexible material.

The second pad portion PDA2 may be located on a fourth side of the display area DAA. For example, in one or more embodiments, the second pad portion PDA2 may be located on the other side of the display area DAA in the second direction DR2. The second pad portion PDA2 may be located outside the second distribution circuit 720 in the second direction DR2. For example, the second pad portion PDA2 may be arranged closer to an edge of the display panel 100 than the second distribution circuit 720.

The first distribution circuit 710 distributes data voltages applied through the first pad portion PDA1 to the plurality of data lines DL. For example, in one or more embodiments, the first distribution circuit 710 may distribute the data voltages applied through one first pad PD1 of the first pad portion PDA1 to P (P is a positive integer of 2 or more) data lines DL, and as a result, the number of the plurality of first pads PD1 may be reduced. The first distribution circuit 710 may be located on the third side of the display area DAA of the display panel 100. For example, the first distribution circuit 710 may be located on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2.

In the context of the present disclosure and unless defined otherwise, “one side of the display area DAA in the second direction DR2” refers to a specific side of the display area along the direction labeled as DR2. For instance, if DR2 represents a vertical direction, this may indicate the bottom side of the display area. Conversely, “the other side of the display area DAA in the second direction DR2” refers to the opposite side of the display area along the same direction DR2, which, continuing the previous example, may indicate the top side of the display area. These phrases are used to describe the positioning of components, such as distribution circuits, on opposite sides of the display area along the specified direction DR2.

A cathode connection portion CCA may be a region in which a second electrode CAT (see FIG. 7) of a display element layer EML (see FIG. 7) is connected to the first driving voltage line VSL of the non-display area NDA. The cathode connection portion CCA may be located outside at least one side of the display area DAA. For example, in one or more embodiments, the cathode connection portion CCA may be located outside at least on one side selected from among the left side, the right side, the upper side, and the lower side of the display area DAA. In one or more embodiments, the cathode connection portion CCA may be located to surround the display area DAA as shown in FIG. 4 in order to minimize or reduce a deviation in the first driving voltage VSS due to a voltage drop (IR drop) or voltage rise (IR rising) of the second electrode CAT in the display area DAA.

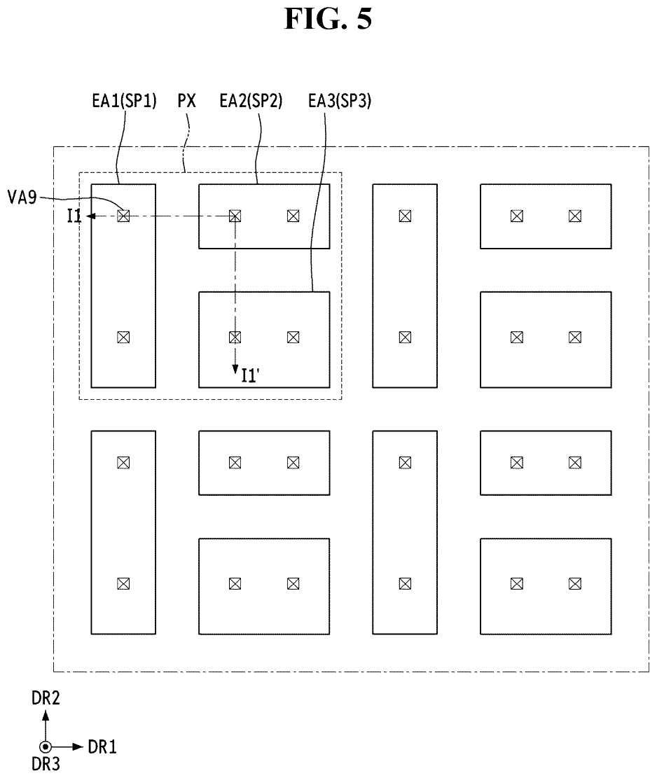

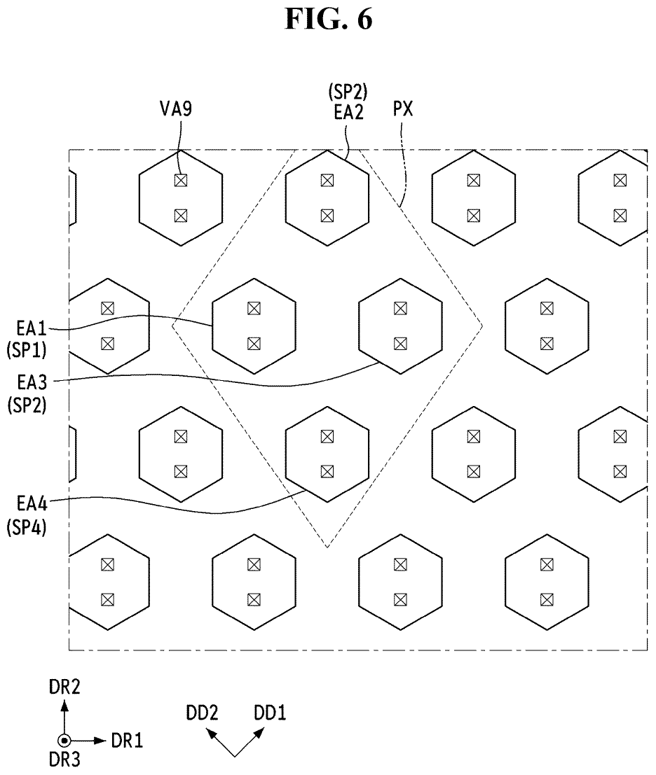

FIG. 5 is a layout diagram showing an example of the display area of FIG. 4 according to one or more embodiments of the present disclosure. FIG. 6 is a layout diagram showing another example of the display area of FIG. 4 according to one or more embodiments of the present disclosure.

Referring to FIG. 5, each of the pixels PX may include a first emission area EA1 that is an emission area of the first sub-pixel SP1, a second emission area EA2 that is an emission area of the second sub-pixel SP2, and a third emission area EA3 that is an emission area of the third sub-pixel SP3. Referring to FIG. 6, each of the pixels PX may include a first emission area EA1 that is an emission area of the first sub-pixel SP1, a second emission area EA2 that is an emission area of the second sub-pixel SP2, a third emission area EA3 that is an emission area of the third sub-pixel SP3, and a fourth emission area EA4 that is an emission area of a fourth sub-pixel SP4. Each of the emission areas may have vias, for example, via VA9, which will be described in more detail later with reference to FIG. 7.

The emission areas, e.g., the first emission area EA1, the second emission area EA2, the third emission area EA3, and the fourth emission area EA4 may each have, in plan view, a quadrilateral shape or a hexagonal shape as shown in FIGS. 5 and 6, but embodiments of the present disclosure are not limited thereto. The first emission area EA1, the second emission area EA2, the third emission area EA3, and fourth emission area EA4 may each have a polygonal shape other than a quadrangle or hexagon, a circular shape, an elliptical shape, or an atypical shape in plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

In one or more embodiments, as shown in FIG. 6, the emission areas EA1, EA2, EA3, and EA4 may each have a hexagonal shape in plan view. In this regard, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

In one or more embodiments, the first sub-pixel SP1 may be to emit first light, the second sub-pixel SP2 may be to emit second light, and the third sub-pixel SP3 may be to emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately (about) 370 nm to (about) 460 nm, the green wavelength band may be a wavelength band of light whose main peak wavelength is in the range of approximately (about) 480 nm to (about) 560 nm, and the red wavelength band may be a wavelength band of light whose main peak wavelength is in the range of approximately (about) 600 nm to (about) 750 nm.

Each of the plurality of pixels PX may include three emission areas EA1, EA2, and EA3 as shown in FIG. 5, or may include four emission areas EA1, EA2, EA3, and EA4 as shown in FIG. 6. In this regard, the fourth emission area EA4 may be to emit the same second light as the second emission area EA2, but embodiments of the present disclosure are not limited thereto.

The emission areas of each of the plurality of pixels PX may be arranged in a stripe structure in which the emission areas are arranged in the first direction DR1, a PenTile® structure in which the emission areas EA1, EA2, EA3, and EA4 are arranged in a rhombus shape, or a hexagonal structure in which the emission areas each having a hexagonal shape are arranged as shown in FIG. 6. PenTile® is a duly registered trademark of Samsung Display Co., Ltd.

FIG. 7 is a cross-sectional view illustrating an example of a display panel taken along the line I1-I1′ of FIG. 5 according to one or more embodiments of the present disclosure.

Referring to FIG. 7, the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may include (e.g., be) the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type (kind) impurity. A plurality of well regions WA may be located on a top surface of the semiconductor substrate SSUB. The plurality of well regions WA may be regions doped with a second type (kind) impurity. The second type (kind) impurity may be different from the aforementioned first type (kind) impurity. For example, in one or more embodiments, if (e.g., when) the first type (kind) impurity is a p-type (kind) impurity, the second type (kind) impurity may be an n-type (kind) impurity. In one or more embodiments, if (e.g., when) the first type (kind) impurity is an n-type (kind) impurity, the second type (kind) impurity may be a p-type (kind) impurity.

Each of the plurality of well regions WA includes a source region SA corresponding to the source electrode of the pixel transistor PTR, a drain region DA corresponding to the drain electrode of the pixel transistor PTR, and a channel region CH located between the source region SA and the drain region DA.

A lower insulating film BINS may be located between a gate electrode GE and the well region WA. A side insulating film SINS may be located on a side surface of the gate electrode GE. The side insulating film SINS may be located on a lower insulating film BINS.

Each of the source region SA and the drain region DA may be a region doped with the first type (kind) impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, which may result in an increase of the length of the channel region CH of each of the pixel transistors PTR.

A first semiconductor insulating film SINS1 may be located on the semiconductor substrate SSUB. A second semiconductor insulating film SINS2 may be located on the first semiconductor insulating film SINS1.

The plurality of contact terminals CTE may be located on the second semiconductor insulating film SINS2. Each of the plurality of contact terminals CTE may be connected to a corresponding one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or an alloy or a compound (each) including any one of them.

A third semiconductor insulating film SINS3 may be located on a side surface of each of the plurality of contact terminals CTE. A top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may independently include silicon carbonitride (SiCN) or a silicon oxide (SiOₓ)-based inorganic film, but embodiments of the present disclosure are not limited thereto.

In one or more embodiments, the semiconductor substrate SSUB may be replaced with a glass substrate or a polymer resin substrate such as polyimide. In these embodiments, thin film transistors may be located on the glass substrate or the polymer resin substrate. The glass substrate may be a rigid substrate that does not bend, and the polymer resin substrate may be a flexible substrate that can be bent or curved.

The light emitting element backplane EBP may include a plurality of conductive layers ML1 to ML8, a plurality of vias VA1 to VA9, and a plurality of insulating films INS1 to INS9. In addition, first to eighth conductive layers ML1 to ML8 may respectively located between first to ninth insulating films INS1 to INS9.

The first to eighth insulating films INS1 to INS8 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 3.

For example, in one or more embodiments, the first to sixth transistors T1 to T6 are merely formed in the semiconductor backplane SBP, and the connection of the first to sixth transistors T1 to T6 and the first and second capacitors CP1 and CP2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may include substantially a same material. The first to eighth conductive layers ML1 to ML8 and the first to eighth vias VA1 to VA8 may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or an alloy or a compound (each) including any one of them. The first to eighth vias VA1 to VA8 may include substantially the same material. in one or more embodiments, the first to eighth insulating films INS1 to INS8 may each be formed as a silicon oxide (SiOₓ)-based inorganic film, but embodiments of the present disclosure are not limited thereto.

The ninth insulating film INS9 may be located on the eighth insulating film INS8 and the eighth conductive layer ML8. In one or more embodiments, the ninth insulating film INS9 may be formed as a silicon oxide (SiOₓ)-based inorganic film, but embodiments of the present disclosure are not limited thereto.

Each of the ninth vias VA9 may penetrate the ninth insulating film INS9 and be connected to the exposed eighth conductive layer ML8. The ninth vias VA9 may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or an alloy or a compound (each) including any one of them.

The display element layer EML may be located on the light emitting element backplane EBP. The display element layer EML may include tenth and eleventh insulating films INS10 and INS11, a reflective electrode RL, first electrodes AND, a light emitting stack IL, the second electrode CAT, a pixel defining film PDL, and a plurality of trenches TRC.

The reflective electrode RL may be located on the ninth insulating film INS9. The reflective electrode RL may include at least one selected from among reflective electrodes RL1, RL2, RL3, and RL4. For example, in one or more embodiments, the reflective electrode RL may include first to fourth reflective electrodes RL1, RL2, RL3, and RL4 as shown in FIG. 7.

The first reflective electrodes RL1 may be located on the ninth insulating film INS9, and may be connected to the ninth via VA9. Each of the second reflective electrodes RL2 may be located on the first reflective electrode RL1 corresponding thereto. Each of the third reflective electrodes RL3 may be located on the second reflective electrode RL2 corresponding thereto. Each of the fourth reflective electrodes RL4 may be located on the third reflective electrode RL3 corresponding thereto.

Because the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or an alloy a compound including any one of them. For example, in one or more embodiments, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

The tenth insulating film INS10 may be located on the ninth insulating film INS9. The tenth insulating film INS10 may be located between the reflective electrodes RL adjacent to each other. The tenth insulating film INS10 may be a film for flattening a stepped portion caused by the reflective electrodes RL. The eleventh insulating film INS11 may be located on the tenth insulating film INS10 and the reflective electrodes RL.

In one or more embodiments, the tenth insulating film INS10 and the eleventh insulating film INS11 may each be formed as a silicon oxide (SiOₓ)-based inorganic film, but embodiments of the present disclosure are not limited thereto.

The eleventh insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh insulating film INS11 may be different in the first sub-pixel SP1, the second sub-pixel SP2, and the third sub-pixel SP3. For example, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh insulating film INS11 may be set for each of the first sub-pixel SP1, the second sub-pixel SP2, and the third sub-pixel SP3.

For example, in one or more embodiments, as shown in FIG. 7, the thickness of the eleventh insulating film INS11 in the first sub-pixel SP1 may be greater than the thickness of the eleventh insulating film INS11 in the second sub-pixel SP2, and the thickness of the eleventh insulating film INS11 in the second sub-pixel SP2 may be greater than the thickness of the eleventh insulating film INS11 in the third sub-pixel SP3. In this regard, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh insulating film INS11 and be connected to the exposed corresponding fourth reflective electrode RL4. The tenth vias VA10 may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or an alloy or a compound (each) including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be located on the eleventh insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or an alloy or a compound (each) including any one of them. For example, in one or more embodiments, the first electrode AND of each of the light emitting elements LE may be titanium nitride (TiN).

The pixel defining film PDL may be located on a part of the first electrode AND of each of the light emitting elements LE. The pixel defining film PDL may cover an edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is located.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be located on the edge of the first electrode AND of each of the light emitting elements LE, the second pixel defining film PDL2 may be located on the first pixel defining film PDL1, and the third pixel defining film PDL3 may be located on the second pixel defining film PDL2. In one or more embodiments, the first pixel defining film PDL1, the second pixel defining film PDL2, and the third pixel defining film PDL3 may each be formed as a silicon oxide (SiOₓ)-based inorganic film. In one or more embodiments, the first pixel defining film PDL1 and the third pixel defining film PDL3 may each be formed as a silicon nitride (SiNₓ)-based inorganic film, whereas the second pixel defining film PDL2 may be formed as a silicon oxide (SiOₓ)-based inorganic film. In one or more embodiments, the first pixel defining film PDL1, the second pixel defining film PDL2, and the third pixel defining film PDL3 may each have a thickness of about 500 Å.

In order to reduce or prevent the likelihood of a first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to a ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. In one or more embodiments, the eleventh insulating film INS11 may be at least partially recessed at each of the plurality of trenches TRC.

At least one trench TRC may be located between neighboring sub-pixels SP1, SP2, and SP3. Although FIG. 7 illustrates that two trenches TRC are located between the neighboring sub-pixels SP1, SP2, and SP3, embodiments of the present disclosure are not limited thereto.

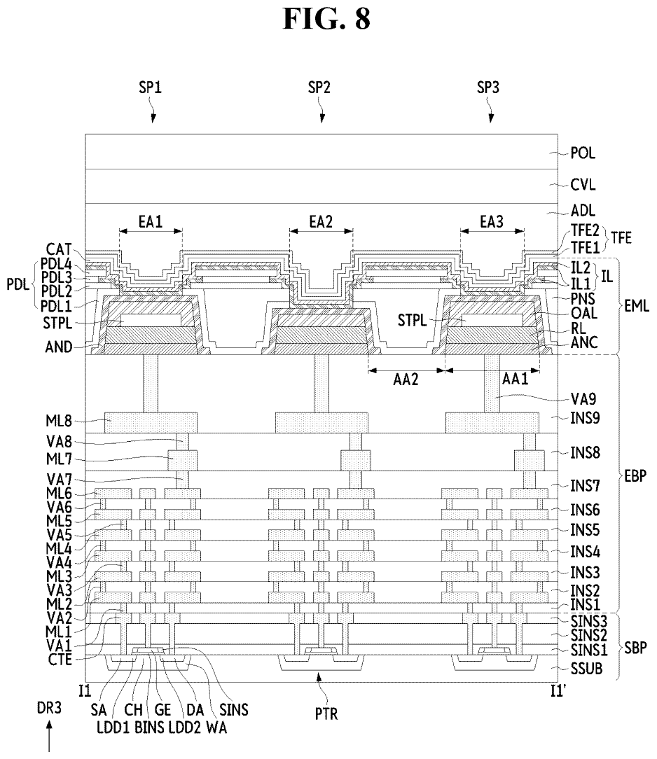

The light emitting stack IL may include a plurality of stack layers IL1, IL2, and IL3. FIG. 7 illustrates that the light emitting stack IL has a three-tandem structure including a first stack layer IL1, a second stack layer IL2, and a third stack layer IL3, but embodiments of the present disclosure are not limited thereto. For example, in one or more embodiments, the light emitting stack IL may have a two-tandem structure including two stack layers as shown in FIG. 8.

In the three-tandem structure, in one or more embodiments, the light emitting stack IL may have a tandem structure including a plurality of stack layers IL1, IL2, and IL3 that emit different lights. For example, the light emitting stack IL may include the first stack layer IL1 that is configured to emit first light, the second stack layer IL2 that is configured to emit second light, and the third stack layer IL3 that is configured to emit third light. The first stack layer IL1, the second stack layer IL2, and the third stack layer IL3 may be sequentially stacked (e.g., in the stated order).

The first stack layer IL1 may have a structure in which a first hole transport layer, a first light emitting layer that emits the first light, and a first electron transport layer are sequentially stacked (e.g., in the stated order). The second stack layer IL2 may have a structure in which a second hole transport layer, a second light emitting layer that emits the second light, and a second electron transport layer are sequentially stacked (e.g., in the stated order). The third stack layer IL3 may have a structure in which a third hole transport layer, a third light emitting layer that emits the third light, and a third electron transport layer are sequentially stacked (e.g., in the stated order).

A first charge generation layer for supplying charges (e.g., holes) to the second stack layer IL2 and supplying electrons to the first stack layer IL1 may be located between the first stack layer IL1 and the second stack layer IL2. The first charge generation layer may include an N-type (kind) charge generation layer that supplies electrons to the first stack layer IL1 and a P-type (kind) charge generation layer that supplies holes to the second stack layer IL2. The N-type (kind) charge generation layer may include a dopant of a metal material.

A second charge generation layer for supplying charges (holes) to the third stack layer IL3 and supplying electrons to the second stack layer IL2 may be located between the second stack layer IL2 and the third stack layer IL3. The second charge generation layer may include an N-type (kind) charge generation layer that supplies electrons to the second stack layer IL2 and a P-type (kind) charge generation layer that supplies holes to the third stack layer IL3.

The first stack layer IL1 may be located on the first electrodes AND and the pixel defining film PDL, and a residual film RIL located on a bottom surface of each trench TRC may be a same material as the first stack layer IL1. Due to the trench TRC, the first stack layer IL1 may be cut off between neighboring sub-pixels SP1, SP2, and SP3. The second stack layer IL2 may be located on the first stack layer IL1. Due to the trench TRC, the second stack layer IL2 may be cut off between the neighboring sub-pixels SP1, SP2, and SP3. A cavity ESS or an empty space may be located between the residual film RIL and the second stack layer IL2 in the trench TRC. The third stack layer IL3 may be located on the second stack layer IL2. The third stack layer IL3 is not cut off by the trench TRC and may be located to cover the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In addition, in the two-tandem structure, each of the plurality of trenches TRC may be a structure for cutting off a lower stack layer and a charge generation layer located between the lower stack layer and an upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to a length of each of the plurality of trenches TRC in the third direction DR3. The height of the pixel defining film PDL refers to a length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, in one or more embodiments, instead of the trench TRC, a reverse tapered partition wall may be located on the pixel defining film PDL.

In addition, FIG. 7 illustrates that the light emitting stack IL that emits light is located in each of the first emission area EA1, the second emission area EA2, and the third emission area EA3, but embodiments of the present disclosure are not limited thereto. For example, in one or more embodiments, instead of the light emitting stack IL, the first light emitting layer may be located in the first emission area EA1, and may not be provided in the second emission area EA2 and the third emission area EA3. Furthermore, the second light emitting layer may be located in the second emission area EA2 and may not be provided in the first emission area EA1 and the third emission area EA3. Furthermore, the third light emitting layer may be located in the third emission area EA3 and may not be provided in the first emission area EA1 and the second emission area EA2. In these embodiments, first to third color filters CF1, CF2, and CF3 of the optical layer OPL may not be provided.

The second electrode CAT may be located on the light emitting stack IL. The second electrode CAT may be located on the third stack layer IL3 in each of the plurality of trenches TRC. In one or more embodiments, the second electrode CAT may include a transparent conductive material (TCO) such as ITO or IZO that may transmit light or a semi-transmissive conductive material such as magnesium (Mg), silver (Ag), or an alloy of magnesium (Mg) and silver (Ag). When the second electrode CAT includes a semi-transmissive conductive material, the light emission efficiency may be improved in each of the first to third sub-pixels SP1, SP2, and SP3 due to a micro-cavity effect.

The encapsulation layer TFE may be located on the display element layer EML. The encapsulation layer TFE may include at least one selected from inorganic films TFE1 and TFE3 to reduce or prevent oxygen and/or moisture from permeating into the display element layer EML. For example, the encapsulation layer TFE includes at least one inorganic film, such as TFE1 or TFE3, to prevent or reduce the permeation of oxygen and/or moisture into the display element layer EML. For example, in one or more embodiments, the encapsulation layer TFE may include both a first encapsulation inorganic film TFE1 and a second encapsulation inorganic film TFE3. The first encapsulation inorganic film TFE1 may be located on the second electrode CAT, and the second encapsulation inorganic film TFE3 may be located on the first encapsulation inorganic film TFE1. The first encapsulation inorganic film TFE1 and the second encapsulation inorganic film TFE3 may each independently be formed as multiple films in which one or more inorganic films of silicon nitride (SiNₓ), silicon oxynitride (SiON), silicon oxide (SiOₓ), titanium oxide (TiOₓ), and aluminum oxide (AlOₓ) layers are alternately stacked.

In addition, the encapsulation layer TFE may include at least one organic film TFE2 to protect the display element layer EML from foreign substances such as dust. The at least one organic film TFE2 of the encapsulation layer TFE may be located between the first encapsulation inorganic film TFE1 and the second encapsulation inorganic film TFE3. In one or more embodiments, the at least one organic film TFE2 of the encapsulation layer TFE may be a monomer. In one or more embodiments, the at least one organic film TFE2 of the encapsulation layer TFE may be an organic film such as formed of an acryl resin, an epoxy resin, a phenolic resin, a polyamide resin, a polyimide resin, and/or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may each be located on the adhesive layer ADL.

The first color filter CF1 may overlap the first emission area EA1 of the first sub-pixel SP1. In one or more embodiments, the first color filter CF1 may be to transmit light of a first color, e.g., light of a blue wavelength band. The blue wavelength band may be about 370 nm to about 460 nm. Thus, the first color filter CF1 may be to transmit light of the first color among light emitted from the first emission area EA1.

The second color filter CF2 may overlap the second emission area EA2 of the second sub-pixel SP2. In one or more embodiments, the second color filter CF2 may be to transmit light of a second color, e.g., light of a green wavelength band. The green wavelength band may be about 480 nm to about 560 nm. Thus, the second color filter CF2 may be to transmit light of the second color among light emitted from the second emission area EA2.

The third color filter CF3 may overlap the third emission area EA3 of the third sub-pixel SP3. In one or more embodiments, the third color filter CF3 may be to transmit light of a third color, e.g., light of a red wavelength band. The red wavelength band may be about 600 nm to about 750 nm. Thus, the third color filter CF3 may be to transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing the proportion of light directed to the front of the display device 10. In one or more embodiments, each of the plurality of lenses LNS may have a cross-sectional shape that is convex in an upward direction. In one or more embodiments, the plurality of lenses LNS may be a micro lens array.

The filling layer FIL may be located on the plurality of lenses LNS. The filling layer FIL may have a selected refractive index such that light travels in the third direction DR3 at an interface between the filling layer FIL and the plurality of lenses LNS. Further, the filling layer FIL may also be a planarization layer. The filling layer FIL may be an organic film such as formed of an acrylic resin, an epoxy resin, a phenolic resin, a polyamide resin, or a polyimide resin.

The cover layer CVL may be located on the filling layer FIL. The cover layer CVL may be a glass substrate or a polymer resin. In one or more embodiments, when the cover layer CVL is a glass substrate, it may be attached onto the filling layer FIL. In these embodiments, the filling layer FIL may serve to bond the cover layer CVL. When the cover layer CVL is a glass substrate, it may serve as an encapsulation substrate. In one or more embodiments, when the cover layer CVL is a polymer resin, it may be directly applied onto the filling layer FIL.

The polarizing plate POL may be located on a (e.g., one) surface of the cover layer CVL. The polarizing plate POL may be a structure for reducing or preventing visibility degradation caused by reflection of external light. The polarizing plate POL may include a linear polarizing plate and a phase retardation film. For example, in one or more embodiments, the phase retardation film may be a λ/4 plate (quarter-wave plate), but embodiments of the present disclosure are not limited thereto. However, if (e.g., when) visibility degradation caused by reflection of external light is sufficiently overcome by the first to third color filters CF1, CF2, and CF3, the polarizing plate POL may not be provided.

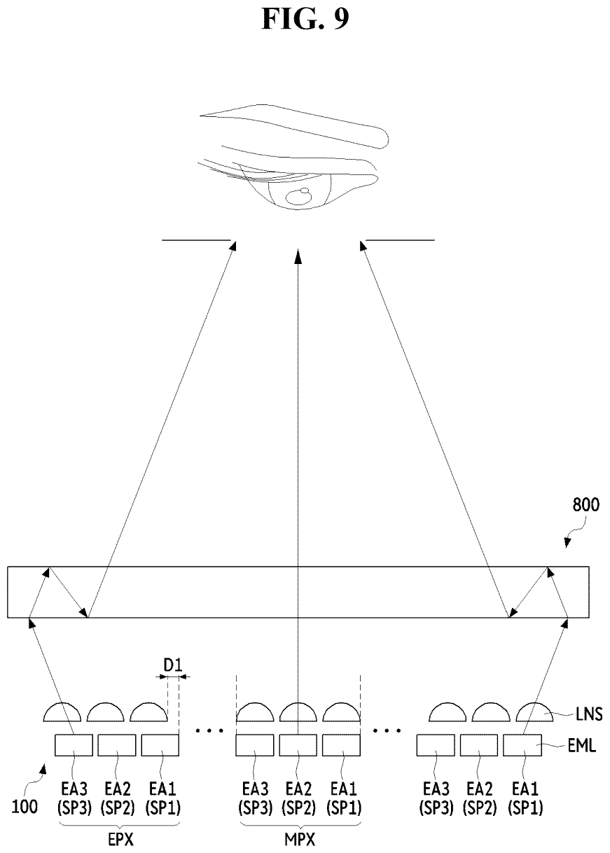

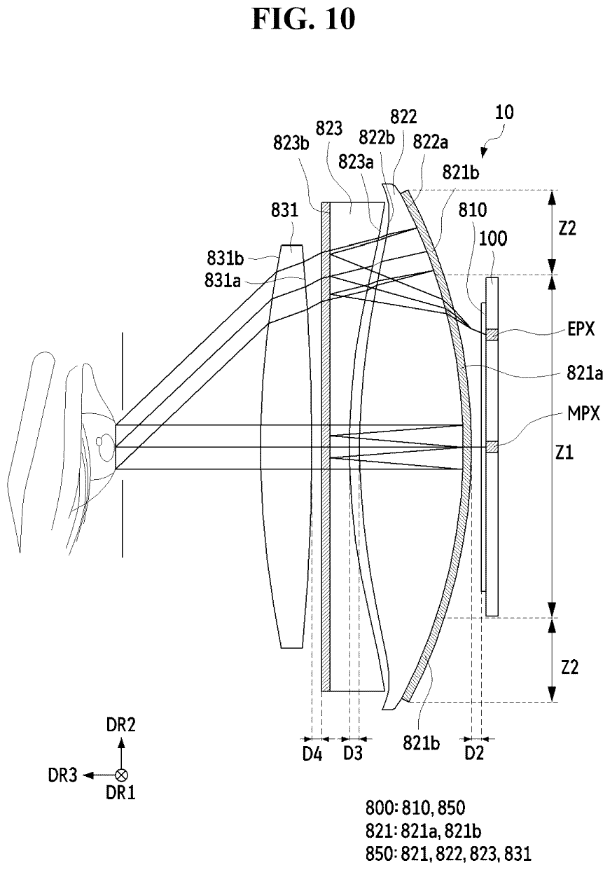

The drawing illustrates that the polarizing plate POL is mounted on the display panel 100, but embodiments of the present disclosure are not limited thereto. For example, the polarizing plate POL may be included in an optical module 800 (see FIG. 9), which will be described later, and in this regard, the polarizing plate POL may have a same component as a first optical module 810 (see FIG. 10) of the optical module 800 (see FIG. 9). For example, the polarizing plate POL may be provided by being mounted on the display panel 100 or may be provided by being mounted on the optical module 800 (see FIG. 9).

FIG. 8 is a cross-sectional view illustrating an example of a display panel taken along the line I1-I1′ of FIG. 5 according to one or more embodiments of the present disclosure.

The embodiment of FIG. 8 differs from the embodiment of FIG. 7 in that the first electrode AND of each of the light emitting elements LE is in contact with and electrically connected to a side surface of a connection electrode ANC connected to the eighth conductive layer ML8. The embodiment of FIG. 8 also differs from the embodiment of FIG. 7 in that the trench TRC is not provided, and instead, the third pixel defining film PDL3 and a fourth pixel defining film PDL4 have an eaves-shaped or mushroom-shaped cross-sectional structure. In the embodiment of FIG. 8, redundant description of parts already described in the embodiment of FIG. 7 will not be provided.

Referring to FIG. 8, the plurality of connection electrodes ANC may be respectively located on first portions AA1 of the ninth insulating film INS9. Each of the plurality of connection electrodes ANC may be located on the first portion AA1 of the ninth insulating film INS9 corresponding thereto. The plurality of connection electrodes ANC may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), an alloy or a compound (each) including any one of them, or a transparent conductive oxide. For example, in one or more embodiments, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively located on the plurality of connection electrodes ANC. Each of the plurality of reflective electrodes RL may be located on the connection electrode ANC corresponding thereto. The plurality of reflective electrodes RL may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or an alloy or a compound (each) including any one of them. For example, in one or more embodiments, each of the plurality of reflective electrodes RL may include aluminum (Al) having high reflectivity.

A plurality of optical auxiliary films OAL may be respectively located on the plurality of reflective electrodes RL. Each of the plurality of optical auxiliary films OAL may be located on the reflective electrode RL corresponding thereto. The plurality of optical auxiliary films OAL may be formed as silicon oxide (SiOₓ)-based inorganic films, but embodiments of the present disclosure are not limited thereto.

In each of the first emission area EA1 and the third emission area EA3, a step layer STPL may be located on the reflective electrode RL, and the optical auxiliary film OAL may be located on the step layer STPL. In the second emission area EA2, only the optical auxiliary film OAL may be located on the reflective electrode RL. The thicknesses of the optical auxiliary films OAL may be substantially the same in the first emission area EA1, the second emission area EA2, and the third emission area EA3.

Due to the step layer STPL, the distance between the reflective electrode RL and the first electrode AND in each of the first emission area EA1 and the third emission area EA3 may be greater than the distance between the reflective electrode RL and the first electrode AND in the second emission area EA2. The thickness of the step layer STPL and the thickness of the optical auxiliary film OAL may be set in consideration of the wavelength and resonance distance of light emitted from the first stack layer IL1 of the light emitting stack IL, and the wavelength and resonance distance of light emitted from the second stack layer IL2.

Each of the light emitting elements LE may include the first electrode AND, the light emitting stack IL, and the second electrode CAT.

The first electrode AND of each of the light emitting elements LE may be located on the optical auxiliary film OAL corresponding thereto. Because the connection electrode ANC, the reflective electrode RL, and the optical auxiliary film OAL are sequentially stacked, the first electrode AND of each of the light emitting elements LE may be located on a top surface and a side surface of the optical auxiliary film OAL, a side surface of the reflective electrode RL, and a side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to when the first electrode AND of each of the light emitting elements LE is connected to the reflective electrode RL exposed through a through hole penetrating the optical auxiliary film OAL, the number of mask processes may be reduced, thereby advantageously lowering manufacturing cost and increasing manufacturing efficiency.

The first electrode AND of each of the light emitting elements LE may be connected to the drain region DA or the source region SA of a corresponding pixel transistor PTR through the connection electrode ANC, the first to ninth vias VA1 to VA9, the first to eighth conductive layers ML1 to ML8, and the contact terminal CTE.

The ninth insulating film INS9 may include the first portion AA1 that overlaps the connection electrode ANC in the third direction DR3 and a second portion AA2 that does not overlap the connection electrode ANC in the third direction DR3. In one or more embodiments, the thickness of the first portion AA1 and the thickness of the second portion AA2 of the ninth insulating film INS9 may be substantially the same.

In one or more embodiments, the thickness of the first portion AA1 of the ninth insulating film INS9 may be greater than the thickness of the second portion AA2. In these embodiments, a side surface of the first portion AA1 of the ninth insulating film INS9 may be exposed, and the first electrode AND of each of the light emitting elements LE may be located on the exposed side surface of the first portion AA1 of the ninth insulating film INS9.

The first electrode AND of each of the light emitting elements LE may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), an alloy or a compound (each) including any one of them, or a transparent conductive oxide. For example, in one or more embodiments, the first electrode AND of each of the light emitting elements LE may include titanium (Ti), titanium nitride (TiN), indium tin oxide (ITO), or indium zinc oxide (IZO), but embodiments of the present disclosure are limited thereto.

The pixel defining film PDL may be located on a part of the first electrode AND of each of the light emitting elements LE. The pixel defining film PDL may cover an edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be located on the first electrode AND of each of the light emitting elements LE. For example, the first pixel defining film PDL1 may cover a part of a top surface of the first electrode AND located on the optical auxiliary film OAL. Further, the first pixel defining film PDL1 may cover the first electrode AND located on the side surface of the connection electrode ANC, the side surface of the reflective electrode RL, and the side surface of the optical auxiliary film OAL. The first pixel defining film PDL1 may be located on a top surface of the second portion AA2 of the ninth insulating film INS9.

A planarization film PNS is a film for flattening the stepped portion caused by the connection electrode ANC, the reflective electrode RL, and the optical auxiliary film OAL.

The planarization film PNS may be located on the first pixel defining film PDL1 covering the first electrode AND located on the side surface of the connection electrode ANC, the side surface of the reflective electrode RL, and the side surface of the optical auxiliary film OAL. The planarization film PNS may be located on the first pixel defining film PDL1 located on the second portion AA2 of the ninth insulating film INS9.

The planarization film PNS may be located between the connection electrodes ANC adjacent in the first direction DR1 or the second direction DR2. The planarization film PNS may be located between the reflective electrodes RL adjacent in the first direction DR1 or the second direction DR2. The planarization film PNS may be located between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, a total height of the connection electrode ANC, the reflective electrode RL, and the optical auxiliary film OAL in the second emission area EA2 may be less than a total height of the connection electrode ANC, the reflective electrode RL, the step layer STPL, and the optical auxiliary film OAL in each of the first emission area EA1 and the third emission area EA3. Therefore, the planarization film PNS may cover the top surface of the first pixel defining film PDL1 located on the top surface of the first electrode AND located in the second emission area EA2.

In contrast, the top surface of the planarization film PNS may be flatly connected to the top surface of the first pixel defining film PDL1 located on the top surface of the first electrode AND located in each of the first emission area EA1 and the third emission area EA3. For example, the planarization film PNS may not cover the top surface of the first pixel defining film PDL1 located on the top surface of the first electrode AND located in each of the first emission area EA1 and the third emission area EA3.

The second pixel defining film PDL2 may be located on the first pixel defining film PDL1 and the planarization film PNS, the third pixel defining film PDL3 may be located on the second pixel defining film PDL2, and the fourth pixel defining film PDL4 may be located on the third pixel defining film PDL3. The first pixel defining film PDL1 and the third pixel defining film PDL3 may each be formed as a silicon nitride (SiNₓ)-based inorganic film, whereas the second pixel defining film PDL2, the fourth pixel defining film PDL4, and the planarization film PNS may each be formed as a silicon oxide (SiOₓ)-based inorganic film. The first pixel defining film PDL1 includes a material different from that of the planarization film PNS, and thus may serve as a stopper in a chemical mechanical polishing process for the planarization film PNS.

When the planarization film PNS and the second pixel defining film PDL2 are both (e.g., simultaneously) formed as silicon oxide (SiOₓ)-based inorganic films, the planarization film PNS and the second pixel defining film PDL2 may be formed as a single film.

Because a length of the third pixel defining film PDL3 in one direction is less than a length of the fourth pixel defining film PDL4 in one direction, a bottom surface of the fourth pixel defining film PDL4 may be exposed without being covered by the third pixel defining film PDL3. For example, the third pixel defining film PDL3 and the fourth pixel defining film PDL4 may have an eaves-shaped or mushroom-shaped cross-sectional structure.

The light emitting stack IL may be located on the first electrode AND and the pixel defining film PDL. The light emitting stack IL may include a first stack layer IL1 and a second stack layer IL2 that emit different lights. When the light emitting stack IL has a two-tandem structure, one among the first stack layer IL1 and the second stack layer IL2 may be to emit light that includes the wavelength range of any one selected from among the first light, the second light, and the third light, and the other may be to emit light that includes the wavelength ranges of the other two lights. For example, in one or more embodiments, the first stack layer IL1 may be to emit light that includes the wavelength range of the first light and the wavelength range of the third light, and the second stack layer IL2 may be to emit light that includes the wavelength range of the second light. Here, the first light may be light of a blue wavelength band, the second light may be light of a green wavelength band, and the third light may be light of a red wavelength band.

A charge generation layer for supplying charges (e.g., holes) to the second stack layer IL2 and supplying electrons to the first stack layer IL1 may be located between the first stack layer IL1 and the second stack layer IL2. The charge generation layer may include an N-type (kind) charge generation layer that supplies electrons to the first stack layer IL1 and a P-type (kind) charge generation layer that supplies holes to the second stack layer IL2. The P-type (kind) charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this regard, a first hole transport layer of the first stack layer IL1, and the charge generation layer located between the first stack layer IL1 and the second stack layer IL2 may also be cut off. Further, although FIG. 8 illustrates that the second stack layer IL2 is connected without being cut off, a second hole transport layer of the second stack layer IL2 may be cut off, and a second electron transport layer of the second stack layer IL2 may be connected without being cut off. Therefore, it may prevent or reduce a leakage current from flowing through the first hole transport layer of the first stack layer IL1, the second hole transport layer of the second stack layer IL2, and the charge generation layer CGL between adjacent emission areas EA1, EA2, and EA3. Accordingly, it may prevent or reduce the light emitting stack IL in the adjacent emission areas EA1, EA2, and EA3 from emitting light other than the originally intended light due to the influence of the above current.

Although FIG. 8 illustrates a two-tandem structure in which the light emitting stack IL includes two stack layers IL1 and IL2, embodiments of the present disclosure are not limited thereto. For example, in one or more embodiments, the light emitting stack IL may have a three-tandem structure including three stack layers as shown in FIG. 7. In these embodiments, it may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. In one or more embodiments, as shown in FIG. 7, a trench TRC penetrating the first pixel defining film PDL1, the planarization film, the second pixel defining film PDL2, and the third pixel defining film PDL3 may be added. In these embodiments, the trench TRC may penetrate at least a part of the ninth insulating film INS9, but embodiments of the present disclosure are not limited thereto.

Although the embodiment of FIG. 8 is illustrated as not including the optical layer OPL of FIG. 7, embodiments of the present disclosure are not limited thereto. The embodiment of FIG. 8 may also further include an optical layer OPL between the adhesive layer ADL and the cover layer CVL.

FIG. 9 is a schematic cross-sectional view illustrating a display element layer, lenses, and an optical module of a display device according to one or more embodiments of the present disclosure.

Referring to FIG. 9 in addition to FIGS. 2 and 7, in one or more embodiments, some among the plurality of lenses LNS may be located in a straight line with each of the emission areas EA1, EA2, and EA3, and some others among the plurality of lenses LNS may be located to be shifted in a (e.g., one) direction with respect to a corresponding emission area among the emission areas EA1, EA2, and EA3.

For example, the display device 10 may include a middle pixel MPX and an edge pixel EPX. The middle pixel MPX refers to the pixel PX positioned in the middle of the display panel 100 among the pixels PX, and the edge pixel EPX refers to the pixel PX positioned at the edge of the display panel 100 among the pixels PX.

The plurality of sub-pixels SP1, SP2, and SP3 included in the middle pixel MPX may be located in parallel with the plurality of lenses LNS located above the sub-pixels SP1, SP2, and SP3, respectively. For example, the plurality of sub-pixels SP1, SP2, and SP3 included in the middle pixel MPX may be respectively located in a straight line in the thickness direction (e.g., the third direction DR3) of the display panel 100 with respect to the plurality of lenses LNS located above the sub-pixels SP1, SP2, and SP3.

The plurality of sub-pixels SP1, SP2, and SP3 included in the edge pixel EPX may be respectively located to be shifted by a first distance D1 with respect to the plurality of lenses LNS located above the sub-pixels SP1, SP2, and SP3. For example, the plurality of sub-pixels SP1, SP2, and SP3 included in the edge pixel EPX may be respectively located to be offset horizontally by the first distance D1 in the thickness direction (e.g., the third direction DR3) of the display panel 100 with respect to the plurality of lenses LNS located above the sub-pixels SP1, SP2, and SP3.

In the display device 10 according to one or more embodiments, the size/magnitude of the first distance D1 that is the degree to which the plurality of sub-pixels SP1, SP2, and SP3 are shifted with respect to their corresponding lenses LNS may increase in the direction from the middle pixel MPX to the edge pixel EPX. Accordingly, the average luminance amount of the display device 10 according to one or more embodiments may be improved according to the chief ray array (CRA) angle distribution. For example, the overall luminous efficiency of the display device 10 may be improved from various (viewing) angles.

For example, if (e.g., when) light emitted from the plurality of sub-pixels SP1, SP2, and SP3 included in the middle pixel MPX is incident on the optical module 800, the light may be incident generally parallel to a normal line (e.g., the vertical arrow line in the drawing). In contrast, if (e.g., when) light emitted from the plurality of sub-pixels SP1, SP2, and SP3 included in the edge pixel EPX is incident on the optical module 800, the light may be incident generally at a selected angle with respect to the normal line. Accordingly, the shift may be performed by the first distance D1 such that the lens LNS (e.g., approximately the middle of the lens LNS) is located on an extension line extending from the display element layer EML of each of the pixels PX to the incident point of the optical module 800, so that the average luminance amount according to the chief ray array (CRA) angle distribution may be improved.

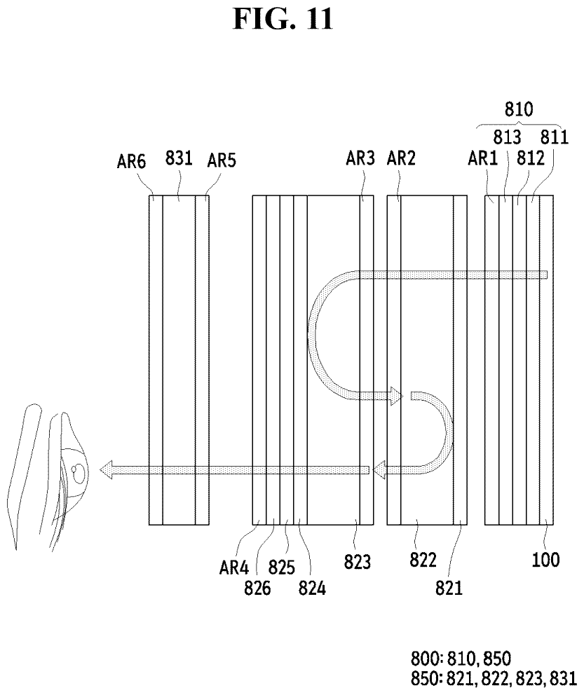

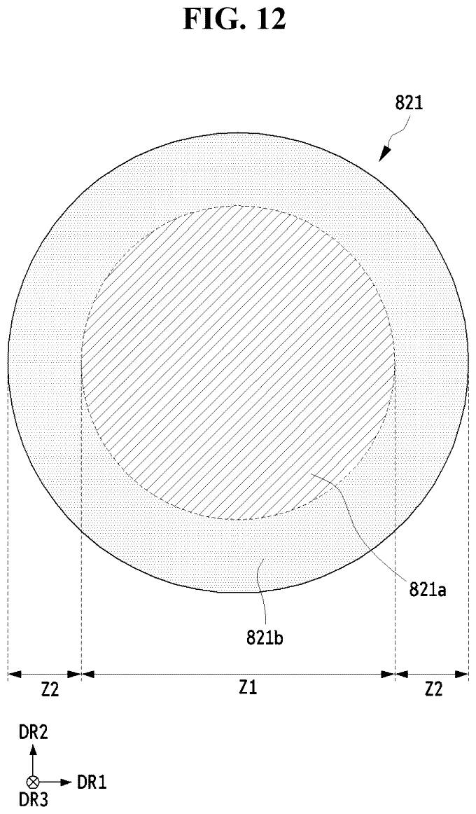

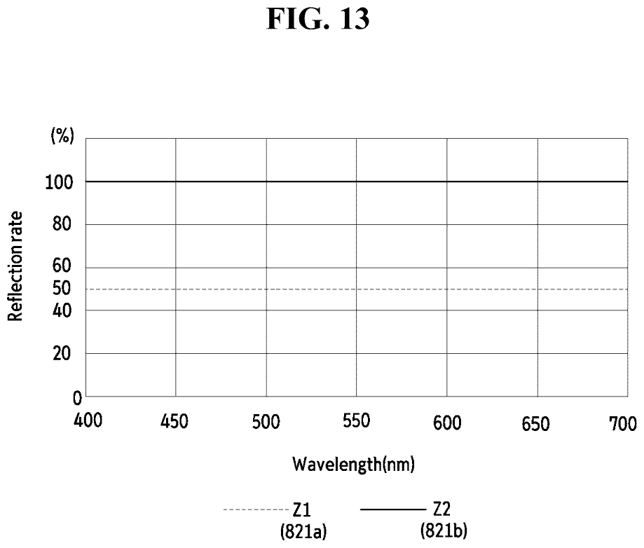

FIGS. 10 and 11 are cross-sectional views showing a display device according to one or more embodiments of the present disclosure. FIG. 12 is a plan view showing a reflection control film according to one or more embodiments of the present disclosure. FIG. 13 is a graph showing reflectivity of a reflection control film according to one or more embodiments of the present disclosure.

Referring to FIGS. 10 to 13 in addition to FIGS. 7 and 9, the display device 10 may include the display panel 100 and the optical module 800 located on the display panel 100.

Because the display panel 100 has been described with reference to FIG. 7 and/or the like, description of the display panel 100 will not be provided.

The optical module 800 may include a first optical module 810 and an optical array module 850. The first optical module 810 may be located on the display panel 100, and the optical array module 850 may be located on the first optical module 810.

In one or more embodiments, the first optical module 810 may be located directly on the display panel 100. For example, the first optical module 810 may be directly attached to the display panel 100.

The optical array module 850 may be spaced and/or apart (e.g., spaced apart or separated) from the first optical module 810 by a second distance D2. An air gap filled with a gas (e.g., air) may be positioned between the optical array module 850 and the first optical module 810.

The first optical module 810 may include a first phase retardation film 811, a first polarizing film 812, a second phase retardation film 813, and a first coating film AR1. The optical array module 850 may include a reflection control film 821, a first lens 822, a second coating film AR2, a third coating film AR3, a second lens 823, a third phase retardation film 824, a second polarizing film 825, a third polarizing film 826, a fourth coating film AR4, a fifth coating film AR5, a third lens 831, and a sixth coating film AR6.

In one or more embodiments, the first optical module 810 may be a same component as the polarizing plate POL of the display panel 100 described with reference to FIG. 7. The display device 10 may include either the polarizing plate POL of the display panel 100 or the first optical module 810 of the optical module 800.

The first phase retardation film 811 may be located on the display panel 100. For example, in one or more embodiments, the first phase retardation film 811 may be located on the cover layer CVL of the display panel 100. The first phase retardation film 811 may delay the phase of light that has passed through the first phase retardation film 811. If (e.g., when) linearly polarized light passes through the first phase retardation film 811, the light may be circularly polarized or elliptically polarized, and if (e.g., when) circularly polarized or elliptically polarized light passes through the first phase retardation film 811, the light may be linearly polarized. In one or more embodiments, the first phase retardation film 811 may be a λ/4 plate (quarter-wave plate). In one or more embodiments, the first phase retardation film 811 may not be provided.

The first polarizing film 812 may be located on the first phase retardation film 811. The first polarizing film 812 may have a first polarization axis extending in one direction. The first polarizing film 812 may be a linear polarizing film. The first polarizing film 812 may linearly polarize light in the direction of the first polarization axis. For example, the first polarizing film 812 may pass light vibrating in a direction parallel to the first polarization axis and may block light vibrating in a direction not parallel to the first polarization axis.

In one or more embodiments, the first polarizing film 812 may be an absorption-type (kind) polarizing film. In this regard, the first polarizing film 812 may pass light vibrating in a direction parallel to the first polarization axis and may be to absorb light vibrating in a direction not parallel to the first polarization axis.

The second phase retardation film 813 may be located on the first polarizing film 812. The second phase retardation film 813 may delay the phase of light that has passed through the second phase retardation film 813. If (e.g., when) linearly polarized light passes through the second phase retardation film 813, the light may be circularly polarized or elliptically polarized, and if (e.g., when) circularly polarized or elliptically polarized light passes through the second phase retardation film 813, the light may be linearly polarized. In one or more embodiments, the second phase retardation film 813 may be a λ/4 plate (quarter-wave plate).

The first coating film AR1 may be located on the second phase retardation film 813. The first coating film AR1 may be an anti-reflection film. The first coating film AR1 may be formed by anti-reflection coating. The first coating film AR1 may prevent or reduce light passing through the top surface (left side in the drawing) of the first optical module 810 from being reflected. Accordingly, the light output efficiency may be improved, and the occurrence of stray light may be minimized or reduced.

The optical array module 850 may include at least one or more lenses. For example, in one or more embodiments, the optical array module 850 may include the first lens 822, the second lens 823, and the third lens 831. In one or more embodiments, the first lens 822, the second lens 823, and the third lens 831 may be located to be spaced and/or apart (e.g., spaced apart or separated) from one another. For example, as illustrated in FIG. 10, the first lens 822 and the second lens 823 may be spaced apart by a third distance D3, and the second lens 823 and the third lens 831 may be spaced apart by a fourth distance D4. The third distance D3 may be a distance between a center portion of the first lens 822 and a center portion of the second lens 823, and the fourth distance D4 may be a distance between a center portion of the second lens 823 and a center portion of the third lens 831. For example, the third distance D3 may be a distance between the center portion of a second surface 822b of the first lens 822 and the center portion of a first surface 823a of the second lens 823, and the fourth distance D4 may be a distance between the center portion of a first surface 831a of the third lens 831 and the center portion of a surface, opposite the first surface 831, of the optical element including the second lens 823.

The first lens 822 may be located on the first optical module 810. For example, the first lens 822 may be located on the first coating film AR1 of the first optical module 810. The first lens 822 may be spaced and/or apart (e.g., spaced apart or separated) from the first optical module 810. The first lens 822 may magnify an image formed by light generated from the display panel 100.

The first lens 822 may be a single lens. The first lens 822 be a magnifying lens. In one or more embodiments, the first lens 822 may include at least one of a convex lens, a meniscus lens, or a Fresnel lens.

In one or more embodiments, the average curvatures of the first surface 822a and the second surface 822b of the first lens 822 may be different. For example, the average curvature of the first surface 822a of the first lens 822 may be greater than the average curvature of the second surface 822b. In one or more embodiments, the first surface 822a and the second surface 822b of the first lens 822 may each be an aspherical surface including a plurality of curvatures. The first surface 822a of the first lens 822 is a surface opposite to (e.g., facing) the first optical module 810, and the second surface 822b is a surface located on the opposite side of the first surface 822a.

In the display device 10 according to one or more embodiments, the first lens 822 may include an aspherical surface, so that the color crosstalk (or color X-talk) phenomenon may be mitigated. In addition, as described above with reference to FIG. 9, by adjusting the first distance D1 that is the degree to which the plurality of sub-pixels SP1, SP2, and SP3 are shifted with respect to the plurality of corresponding lenses LNS in the direction from the middle pixel MPX to the edge pixel EPX and concurrently (e.g., simultaneously) adjusting each of the plurality of curvatures of the aspherical surface of the first lens 822, the average luminance amount according to the chief ray array (CRA) angle distribution may be further improved.

The reflection control film 821 may be located on the first lens 822. For example, the reflection control film 821 may be located on the first surface 822a of the first lens 822. The reflection control film 821 may be located between the first lens 822 and the first optical module 810. The reflection control film 821 may be configured to transmit part of incident light and reflect the remaining part. For example, the reflection control film 821 may include a half mirror.

Light transmitted through the reflection control film 821 may be transmitted without phase change. Light reflected from the reflection control film 821 may be reflected with its phase reversed. For example, left-circularly polarized light may be reflected from the reflection control film 821 to be right-circularly polarized light, and the right-circularly polarized light may be reflected from the reflection control film 821 to be left-circularly polarized light.

The reflection control film 821 may be conformally formed according to a shape of the first surface 822a of the first lens 822. Because the first surface 822a of the first lens 822 is an aspherical surface including a plurality of curvatures, the viewing angle and the magnification ratio may be increased. Accordingly, the number of components of the optical module 800 may be reduced and the thickness of the display device 10 may be reduced.

The second coating film AR2 may be located on the first lens 822. For example, in one or more embodiments, the second coating film AR2 may be located on the second surface 822b of the first lens 822. The second coating film AR2 may be an anti-reflection film. The second coating film AR2 may be formed by anti-reflection coating. The second coating film AR2 may prevent or reduce light passing through the second surface 822b of the first lens 822 from being reflected. Accordingly, the light output efficiency may be improved, and the occurrence of stray light may be minimized or reduced.

The second lens 823 may be located on the first lens 822. For example, in one or more embodiments, the second lens 823 may be located on the second coating film AR2 of the first lens 822. The second lens 823 may be spaced and/or apart (e.g., spaced apart or separated) from the first lens 822. The second lens 823 may magnify an image formed by light generated from the display panel 100.

The second lens 823 may be a single lens. The second lens 823 may be a magnifying lens. In one or more embodiments, the second lens 823 may include at least one of a convex lens, a meniscus lens, or a Fresnel lens.

In one or more embodiments, the average curvatures of the first surface 823a and a second surface 823b of the second lens 823 may be different. For example, the average curvature of the first surface 823a of the second lens 823 may be greater than the average curvature of the second surface 823b of the second lens 823. In one or more embodiments, the first surface 823a of the second lens 823 may be an aspherical surface including a plurality of curvatures, and the second surface 823b may be a flat surface. The first surface 823a of the second lens 823 may be a surface opposite to (e.g., facing) the first lens 822, and the second surface 823b may be a surface located on the opposite side of the first surface 823a.

In the display device 10 according to one or more embodiments, the second lens 823 may include an aspherical surface, so that the color crosstalk (or color X-talk) phenomenon may be mitigated. In addition, as described above with reference to FIG. 9, by adjusting the first distance D1 that is the degree to which the plurality of sub-pixels SP1, SP2, and SP3 are shifted with respect to the plurality of corresponding lenses LNS in the direction from the middle pixel MPX to the edge pixel EPX and concurrently (e.g., simultaneously) adjusting each of the plurality of curvatures of the aspherical surface of the second lens 823, the average luminance amount according to the chief ray array (CRA) angle distribution may be further improved.

The third coating film AR3 may be located on the second lens 823. For example, in one or more embodiments, the third coating film AR3 may be located on the first surface 823a of the second lens 823. The third coating film AR3 may be an anti-reflection film. The third coating film AR3 may be formed by anti-reflection coating. The third coating film AR3 may prevent or reduce light passing through the first surface 823a of the second lens 823 from being reflected. Accordingly, the light output efficiency may be improved, and the occurrence of stray light may be minimized or reduced.

The third phase retardation film 824 may be located on the second lens 823. For example, in one or more embodiments, the third phase retardation film 824 may be located on the second surface 823b of the second lens 823. The third phase retardation film 824 may delay the phase of light that has passed through the third phase retardation film 824. If (e.g., when) linearly polarized light passes through the third phase retardation film 824, the light may be circularly polarized or elliptically polarized, and if (e.g., when) circularly polarized or elliptically polarized light passes through the third phase retardation film 824, the light may be linearly polarized. In one or more embodiments, the third phase retardation film 824 may be a λ/4 plate (quarter-wave plate).

The second polarizing film 825 may be located on the third phase retardation film 824. The second polarizing film 825 may have a second polarization axis extending in one direction. The second polarizing film 825 may be a linear polarizing film. The second polarizing film 825 may linearly polarize light in the direction of the second polarization axis. For example, the second polarizing film 825 may pass light vibrating in a direction parallel to the second polarization axis and may block light vibrating in a direction not parallel to the second polarization axis.

In one or more embodiments, the second polarizing film 825 may be a reflective polarizing film. In this regard, the second polarizing film 825 may pass light vibrating in a direction parallel to the second polarization axis and may reflect light vibrating in a direction not parallel to the second polarization axis.

The third polarizing film 826 may be located on the second polarizing film 825. The third polarizing film 826 may have a third polarization axis extending in one direction. The third polarizing film 826 may be a linear polarizing film. The third polarizing film 826 may linearly polarize light in the direction of the third polarization axis. For example, the third polarizing film 826 may pass light vibrating in a direction parallel to the third polarization axis and may block light vibrating in a direction not parallel to the third polarization axis. In one or more embodiments, the third polarizing film 826 may not be provided.

In one or more embodiments, the third polarizing film 826 may be an absorption-type (kind) polarizing film. In this regard, the third polarizing film 826 may pass light vibrating in a direction parallel to the third polarization axis and may be to absorb light vibrating in a direction not parallel to the third polarization axis.

The fourth coating film AR4 may be located on the second surface 823b of the second lens 823. For example, in one or more embodiments, the fourth coating film AR4 may be located on the third polarizing film 826. The fourth coating film AR4 may be an anti-reflection film. The fourth coating film AR4 may be formed by anti-reflection coating. The fourth coating film AR4 may prevent or reduce light passing through the second surface 823b of the second lens 823 from being reflected. Accordingly, the light output efficiency may be improved, and the occurrence of stray light may be minimized or reduced.

In one or more embodiments, the third phase retardation film 824, the second polarizing film 825, the third polarizing film 826, and the fourth coating film AR4 may be conformally formed according to a shape of the second surface 823b of the second lens 823.

The third lens 831 may be located on the second lens 823. For example, in one or more embodiments, the third lens 831 may be located on the fourth coating film AR4. The third lens 831 may be spaced and/or apart (e.g., spaced apart or separated) from the second lens 823. The third lens 831 may magnify an image formed by light generated from the display panel 100.

The third lens 831 may be a single lens. The third lens 831 may be a magnifying lens. In one or more embodiments, the third lens 831 may include at least one of a convex lens, a meniscus lens, or a Fresnel lens.

In one or more embodiments, the average curvatures of a first surface 831a and a second surface 831b of the third lens 831 may be different. For example, the average curvature of the first surface 831a of the third lens 831 may be smaller than the average curvature of the second surface 831b. In one or more embodiments, each of the first surface 831a and the second surface 831b of the third lens 831 may be an aspherical surface including a plurality of curvatures. The first surface 831a of the third lens 831 may be a surface opposite to (e.g., facing) the second lens 823, and the second surface 831b may be a surface located on the opposite side of the first surface 831a.

In the display device 10 according to one or more embodiments, the third lens 831 may include an aspherical surface, so that the color crosstalk (or color X-talk) phenomenon may be mitigated. In addition, as described above with reference to FIG. 9, by adjusting the first distance D1 that is the degree to which the plurality of sub-pixels SP1, SP2, and SP3 are shifted with respect to the plurality of corresponding lenses LNS in the direction from the middle pixel MPX to the edge pixel EPX and concurrently (e.g., simultaneously) adjusting each of the plurality of curvatures of the aspherical surface of the third lens 831, the average luminance amount according to the chief ray array (CRA) angle distribution may be further improved.

The fifth coating film AR5 may be located on the first surface 831a of the third lens 831. For example, in one or more embodiments, the fifth coating film AR5 may be located on the fourth coating film AR4. The fifth coating film AR5 may be an anti-reflection film. The fifth coating film AR5 may be formed by anti-reflection coating. The fifth coating film AR5 may prevent or reduce light passing through the first surface 831a of the third lens 831 from being reflected. Accordingly, the light output efficiency may be improved, and the occurrence of stray light may be minimized or reduced.

The sixth coating film AR6 may be located on the second surface 831b of the third lens 831. The sixth coating film AR6 may be an anti-reflection film. The sixth coating film AR6 may be formed by anti-reflection coating. The sixth coating film AR6 may prevent or reduce light passing through the second surface 831b of the third lens 831 from being reflected. Accordingly, the light output efficiency may be improved, and the occurrence of stray light may be minimized or reduced.

In one or more embodiments, at least one selected from among the first to sixth coating films AR1 to AR6 may not be provided depending on the degree of improvement in transmittance and reflectivity of each member.

The first polarization axis of the first polarizing film 812 and the second polarization axis of the second polarizing film 825 may be perpendicular to each other. For example, if (e.g., when) the first polarization axis extends in the third direction DR3 that is a perpendicular direction, the second polarization axis may extend in a horizontal direction perpendicular to the third direction DR3.

The second phase retardation film 813 may have a first optical axis. The first optical axis of the second phase retardation film 813 may be tilted by an angle in the range of greater than 0 degrees and less than 90 degrees relative to the first polarization axis of the first polarizing film 812 and/or the second polarization axis of the second polarizing film 825. In one or more embodiments, the first optical axis may be tilted by an angle of approximately 45 degrees relative to the first polarization axis of the first polarizing film 812 and/or the second polarization axis of the second polarizing film 825, but embodiments of the present disclosure are not limited thereto.

The third phase retardation film 824 may have a second optical axis. The second optical axis of the third phase retardation film 824 may be tilted by an angle in the range of greater than 0 degrees and less than 90 degrees relative to the first polarization axis of the first polarizing film 812 and/or the second polarization axis of the second polarizing film 825. In one or more embodiments, the second optical axis may be tilted by an angle of approximately 45 degrees relative to the first polarization axis of the first polarizing film 812 and/or the second polarization axis of the second polarizing film 825, but embodiments of the present disclosure are not limited thereto.

The direction in which the first optical axis of the second phase retardation film 813 is tilted with respect to the first polarization axis of the first polarizing film 812 and/or the second polarization axis of the second polarizing film 825 may be opposite to the direction in which the second optical axis of the third phase retardation film 824 is tilted with respect to the first polarization axis of the first polarizing film 812 and/or the second polarization axis of the second polarizing film 825. For example, in one or more embodiments, the second phase retardation film 813 may be tilted in the −45 degree direction with respect to the first polarization axis of the first polarizing film 812 and/or the second polarization axis of the second polarizing film 825, and the third phase retardation film 824 may be tilted in the +45 degree direction with respect to the first polarization axis of the first polarizing film 812 and/or the second polarization axis of the second polarizing film 825. In one or more embodiments, the second phase retardation film 813 may be tilted in the +45 degree direction with respect to the first polarization axis of the first polarizing film 812 and/or the second polarization axis of the second polarizing film 825, and the third phase retardation film 824 may be tilted in the −45 degree direction with respect to the first polarization axis of the first polarizing film 812 and/or the second polarization axis of the second polarizing film 825.

The phase retardation direction of light that has passed through the second phase retardation film 813 may be different from the phase retardation direction of light that has passed through the third phase retardation film 824. For example, in one or more embodiments, light that has passed through the second phase retardation film 813 may be delayed by −λ/4, and light that has passed through the third phase retardation film 824 may be delayed by +λ/4.

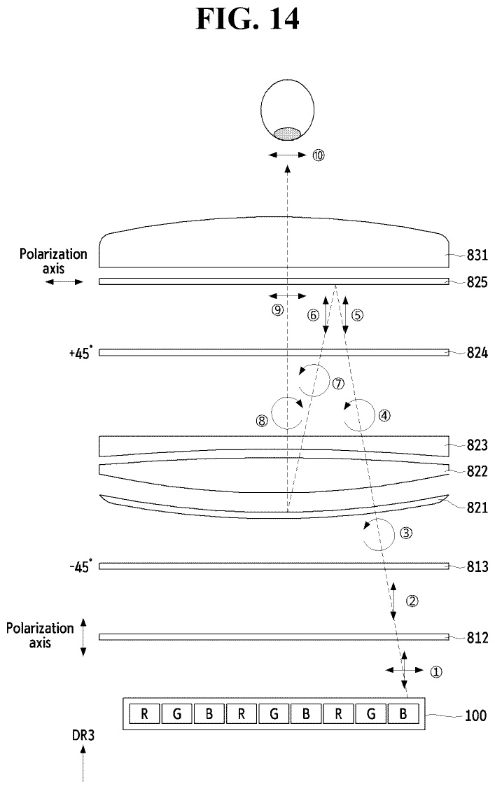

The display device 10 according to one or more embodiments may implement folded optics that folds the optical path by including the optical module 800. Accordingly, a total track length, which is the total length of the optical path, may be increased while concurrently (e.g., simultaneously) minimizing or reducing the thickness of the display device 10. This will be described later with reference to FIG. 14.

In the display device 10 according to one or more embodiments, the reflection control film 821 may include a first portion 821a and a second portion 821b.

As illustrated in FIG. 12, the first portion 821a may be located at a center portion of the reflection control film 821 and the second portion 821b may be located on an edge of the reflection control film 821. The second portion 821b may surround the first portion 821a in plan view.

The first portion 821a may be to transmit part of incident light and reflect the remaining part. The second portion 821b may reflect the entire incident light. For example, the reflectivity and the transmittance of the first portion 821a may each be approximately 47% to 53%, the reflectivity of the second portion 821b may be approximately 80% or more, and the transmittance of the second portion 821b may be approximately less than 20%. In one or more embodiments, the reflectivity of the second portion 821b may be 95% or more, and the transmittance of the second portion 821b may be approximately less than 5%.

In the present disclosure, reflectivity and transmittance refer to reflectivity and transmittance for visible light wavelengths. For example, reflectivity and transmittance in the present disclosure may refer to reflectivity for wavelengths of approximately 400 nm to 700 nm.

FIG. 13 is a graph showing an example reflectivity of the first portion 821a and the second portion 821b when the display device 10 has the maximum luminous efficiency. As illustrated in FIG. 13, if (e.g., when) the reflectivity of the first portion 821a is approximately 50% and the reflectivity of the second portion 821b is approximately 100%, the display device 10 may have maximum luminous efficiency.

The first portion 821a may have a half mirror. The half mirror refers to a mirror having a lower reflectivity than a regular mirror to be described later. For one example, the half mirror may refer to a mirror with reflectivity of less than 80%.

In one or more embodiments, the first portion 821a may include a multilayer film in which low-refractive-index inorganic insulating films and high-refractive-index inorganic insulating films are alternately stacked. For example, the low-refractive-index inorganic insulating film may include at least one of silicon oxide (SiOₓ) or silicon oxynitride (SiOₓN_{y}), and the high-refractive-index inorganic insulating film may include at least one of silicon nitride (SiNₓ) or titanium oxide (TiOₓ). In one or more embodiments, the multilayer films of the first portion 821a may be formed by a physical vapor deposition process such as sputtering, chemical vapor deposition, or coating processes.

The second portion 821b may have a regular mirror. The regular mirror refers to a mirror having a higher reflectivity than the half mirror described above. For one example, the regular mirror may refer to a mirror with reflectivity of 80% or more.

In one or more embodiments, the second portion 821b may include a substrate including glass, quartz, or a metal material; a reflective layer including a highly reflective metal material; and a protective layer. For example, the metal material included in the reflective layer may include at least one of aluminum (Al), silver (Ag), gold (Au), or an alloy thereof.

As illustrated in FIG. 10, light emitted from the middle pixel MPX may be transmitted through the first portion 821a and then reflected again from the first portion 821a through the subsequent optical path (see FIG. 14). In contrast, light emitted from the edge pixel EPX may be transmitted through the first portion 821a and then reflected through the second portion 821b through the subsequent optical path (see FIG. 14).

For example, the first portion 821a may be located in a first region Z1 where both (e.g., simultaneously) transmission and reflection of light occur, and the second portion 821b may be located in a second region Z2 where only light reflection substantially occurs. The first region Z1 and the second region Z2 may be distinguished as follows. For example, the region where light emitted from the outermost pixel among the edge pixels EPX passes through the reflection control film 821 may be the first region Z1, and the region excluding the first region Z1, where light emitted from the display panel 100 does not pass through, may be the second region Z2.

In the display device 10 according to one or more embodiments, as the first portion 821a of the reflection control film 821 includes a half mirror because both (e.g., simultaneously) transmission and reflection of light must occur in the first region Z1, and the second portion 821b of the reflection control film 821 includes a regular mirror because only reflection of light must occur in the second region Z2, the luminous efficiency of the display device 10 may be increased.

FIG. 14 is a schematic diagram illustrating the path and polarization state of light emitted from a display device according to one or more embodiments of the present disclosure.

Referring to FIG. 14 in addition to FIGS. 10 and 11, it is illustrated that the first polarization axis of the first polarizing film 812 extends in the perpendicular direction and the second polarization axis of the second polarizing film 825 extends in the horizontal direction. In addition, it is illustrated that the first polarizing film 812 is an absorption-type (kind) polarizing film and the second polarizing film 825 is a reflective polarizing film. In addition, it is illustrated that the first optical axis of the second phase retardation film 813 is tilted by −45 degrees with respect to the perpendicular direction and the second optical axis of the third phase retardation film 824 is tilted by +45 degrees with respect to the perpendicular direction.

Light emitted from the display panel 100 may be unpolarized light \textcircled{1}.

The unpolarized light \textcircled{1} may pass through the first polarizing film 812 with the first polarization axis in the perpendicular direction and be converted into vertical linear polarized light \textcircled{2} that vibrates in the perpendicular direction.

The vertical linear polarized light \textcircled{2} that has passed through the first polarizing film 812 may pass through the second phase retardation film 813 with the first optical axis tilted by −45 degrees with respect to the perpendicular direction and be converted into left-circularly polarized light \textcircled{3}.

Part of the left-circularly polarized light \textcircled{3} that has passed through the second phase retardation film 813 may pass through reflection control film 821. The left-circularly polarized light \textcircled{3} that has passed through the reflection control film 821 may have the same polarization state as the left-circularly polarized light \textcircled{3} that has passed through the second phase retardation film 813 without any change in the polarization state. Although not illustrated in FIG. 14, the remaining part of the left-circularly polarized light \textcircled{3} that has passed through the second phase retardation film 813 may be reflected by the reflection control film 821.

The left-circularly polarized light \textcircled{3} that has passed through the reflection control film 821 may pass through the first lens 822 and the second lens 823, and the image may be magnified. Left-circularly polarized light \textcircled{4} that has passed through the first lens 822 and the second lens 823 may have the same polarization state as the left-circularly polarized light \textcircled{3} that has passed through the reflection control film 821 without any change in the polarization state.

The left-circularly polarized light \textcircled{4} that has passed through the first lens 822 and the second lens 823 may pass through the third phase retardation film 824 with the second optical axis tilted by +45 degrees with respect to the perpendicular direction and be converted back into vertical linear polarized light \textcircled{5}.

Because the vertical linear polarized light \textcircled{5} that has passed through the third phase retardation film 824 is light polarized in a direction different from the second polarization axis in the horizontal direction, the light may be reflected by the second polarizing film 825. Vertical linear polarized light \textcircled{6} reflected from the second polarizing film 825 may have the same polarization state as the vertical linear polarized light \textcircled{5} that has passed through the third phase retardation film 824 without any change in the polarization state.

The vertical linear polarized light \textcircled{6} reflected from the second polarizing film 825 may pass through the third phase retardation film 824 with the second optical axis tilted by +45 degrees with respect to the perpendicular direction and be converted into left-circularly polarized light \textcircled{7}. When the vertical linear polarized light \textcircled{2} that has passed through the first polarizing film 812 passes through the second phase retardation film 813, the light may pass through the second phase retardation film 813, which has the first optical axis tilted by −45 degrees with respect to the perpendicular direction, in the third direction DR3 and thus be converted into the left-circularly polarized light \textcircled{3}, and on the other hand, the vertical linear polarized light \textcircled{6} reflected from the second polarizing film 825 may pass through the third phase retardation film 824, which has the second optical axis tilted by +45 degrees with respect to the perpendicular direction, in a direction opposite to the third direction DR3 and thus be converted into the left-circularly polarized light \textcircled{7}.

The left-circularly polarized light \textcircled{7} that has passed through the third phase retardation film 824 may pass through the second lens 823 and the first lens 822, so that the image may be magnified once more. The left-circularly polarized light \textcircled{7} that has passed through the second lens 823 and the first lens 822 may have the same polarization state as the left-circularly polarized light \textcircled{7} that has passed through the third phase retardation film 824 without any change in the polarization state.

Part of the left-circularly polarized light \textcircled{7} that has passed through the second lens 823 and the first lens 822 may be reflected by the reflection control film 821 and be converted into right-circularly polarized light \textcircled{8} by the left and right inversion effect.

The right-circularly polarized light \textcircled{8} reflected from the reflection control film 821 may pass through the first lens 822 and the second lens 823, so that the image may be magnified once more. The right-circularly polarized light \textcircled{8} that has passed through the first lens 822 and the second lens 823 may have the same polarization state as the right-circularly polarized light \textcircled{8} reflected from the reflection control film 821 without any change in the polarization state.

The right-circularly polarized light \textcircled{8} that has passed through the first lens 822 and the second lens 823 may pass through the third phase retardation film 824 with the second optical axis tilted by +45 degrees and be converted into horizontal linear polarized light \textcircled{9}.

Because the horizontal linear polarized light \textcircled{9} that has passed through the third phase retardation film 824 is light polarized in the same direction as the second polarization axis of the second polarizing film 825 in the horizontal direction, the light may pass through the second polarizing film 825. The horizontal linear polarized light \textcircled{9} that has passed through the second polarizing film 825 may have the same polarization state as the horizontal linear polarized light \textcircled{9} that has passed through the third phase retardation film 824 without any change in the polarization state.

The horizontal linear polarized light \textcircled{9} that has passed through the second polarizing film 825 may pass through the third lens 831, and the image may be magnified. Horizontal linear polarized light \textcircled{10} that has passed through the third lens 831 may have the same polarization state as the horizontal linear polarized light \textcircled{9} that has passed through the second polarizing film 825 without any change in the polarization state. The horizontal linear polarized light \textcircled{10} that has passed through the third lens 831 may be provided to a user.

Because the display device 10 according to one or more embodiments includes folded optics, light passes through three lenses a total of seven times, so that the frequency at which the image is magnified increases, and the degree to which the image is magnified may increase because the optical path increases. Accordingly, the thickness of the display device 10 may be reduced, but a more magnified image may be acquired.

Hereinafter, other embodiments of the display device according to one or more embodiments will be described. In the following embodiments, description of the same components as those of the above-described embodiment, which are denoted by like reference numerals, will not be provided or will be simplified, and differences will be mainly described.

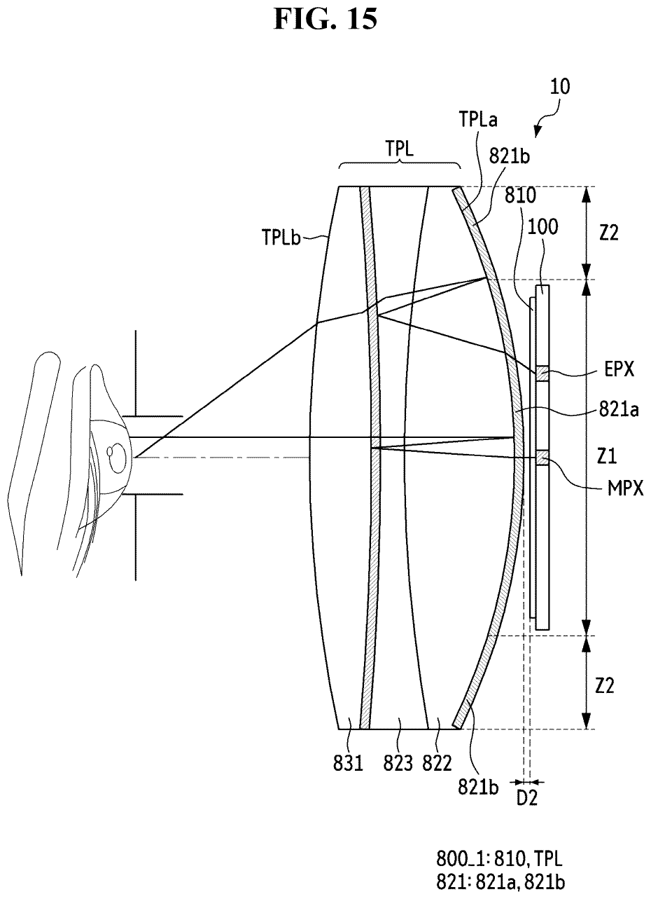

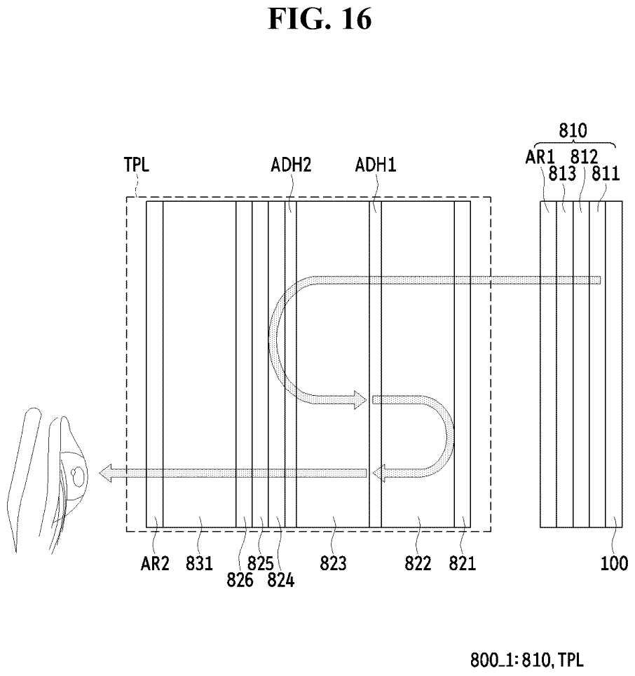

FIGS. 15 and 16 are cross-sectional views showing a display device according to one or more embodiments of the present disclosure.

Referring to FIGS. 15 and 16, the display device 10 according to one or more embodiments is different from the display device 10 according to the embodiments described above with reference to FIG. 10 and/or the like in that an optical array module TPL is a triplet lens.

For example, an optical module 800_1 may include a first optical module 810, and the optical array module TPL. The first optical module 810 may be located on the display panel 100, and the optical array module TPL may be located on the first optical module 810.

The optical array module TPL may include a reflection control film 821, a first lens 822, a first adhesive layer ADH1, a second lens 823, a second adhesive layer ADH2, a third phase retardation film 824, a second polarizing film 825, a third polarizing film 826, a third lens 831, and a second coating film AR2.

The optical array module TPL may be a triplet lens. For example, the optical array module TPL may be a lens in which the first lens 822, the second lens 823, and the third lens 831 are combined. The first adhesive layer ADH1 may be arranged between the first lens 822 and the second lens 823, and the second adhesive layer ADH2 may be arranged between the second lens 823 and the third lens 831. The first lens 822, the second lens 823, and the third lens 831 may be combined with one another by the first adhesive layer ADH1 and the second adhesive layer ADH2.

The display device 10 according to one or more embodiments may reduce the thickness of the optical module 800_1 by including a triplet lens. Accordingly, it may become easier to ensure the optimal or suitable distance for eye relief. Additionally, the field of view (FOV) may be increased through aberration correction and focus correction by using a triplet lens. Further, because the triplet lens is included, an air gap located between separate lenses spaced and/or apart from each other may be eliminated, and light loss due to reflection at an interface between the air gap and the lens may be minimized or reduced, thereby increasing light efficiency.

In one or more embodiments, the average curvatures of a first surface TPLa and a second surface TPLb of the optical array module TPL may be different. For example, the average curvature of the first surface TPLa of the optical array module TPL may be greater than the average curvature of the second surface TPLb. In one or more embodiments, the first surface TPLa and the second surface TPLb of the optical array module TPL may each be an aspherical surface including plurality of curvatures. The first surface TPLa of the optical array module TPL is a surface opposite to (e.g., facing) the first optical module 810, and the second surface TPLb is a surface located on the opposite side of the first surface TPLa.

In the display device 10 according to one or more embodiments, the optical array module TPL may include an aspherical surface, so that the color crosstalk (or color X-talk) phenomenon may be mitigated. In addition, as described above with reference to FIG. 9, by adjusting the first distance D1 that is the degree to which the plurality of sub-pixels SP1, SP2, and SP3 are shifted with respect to the plurality of corresponding lenses LNS in the direction from the middle pixel MPX to the edge pixel EPX and concurrently (e.g., simultaneously) adjusting each of the plurality of curvatures of the aspherical surface of the optical array module TPL, the average luminance amount according to the chief ray array (CRA) angle distribution may be further improved.

The reflection control film 821 may be located on the first surface TPLa of the optical array module TPL. For example, the reflection control film 821 may be located on the first lens 822. The reflection control film 821 may be located between the first lens 822 and the first optical module 810. The reflection control film 821 may be to transmit part of incident light and reflect the remaining part. For example, the reflection control film 821 may include a half mirror.

Light transmitted through the reflection control film 821 may be transmitted without phase change. Light reflected from the reflection control film 821 may be reflected with its phase reversed. For example, left-circularly polarized light may be reflected from the reflection control film 821 to be right-circularly polarized light, and the right-circularly polarized light may be reflected from the reflection control film 821 to be left-circularly polarized light.

The reflection control film 821 may be conformally formed according to a shape of the first surface TPLa of the optical array module TPL. Because the first surface TPLa of the optical array module TPL is an aspherical surface including a plurality of curvatures, the viewing angle and the magnification ratio may be increased. Accordingly, the number of components of the optical module 800_1 may be reduced and the thickness of the display device 10 may be reduced.

The third phase retardation film 824 may be located on the second lens 823. For example, in one or more embodiments, the third phase retardation film 824 may be bonded to the second lens 823 via the second adhesive layer ADH2. The third phase retardation film 824 may delay the phase of light that has passed through the third phase retardation film 824. If (e.g., when) linearly polarized light passes through the third phase retardation film 824, the light may be circularly polarized or elliptically polarized, and if (e.g., when) circularly polarized or elliptically polarized light passes through the third phase retardation film 824, the light may be linearly polarized. In one or more embodiments, the third phase retardation film 824 may be a λ/4 plate (quarter-wave plate).

The second polarizing film 825 may be located on the third phase retardation film 824. The second polarizing film 825 may have a second polarization axis extending in one direction. The second polarizing film 825 may be a linear polarizing film. The second polarizing film 825 may linearly polarize light in the direction of the second polarization axis. For example, the second polarizing film 825 may pass light vibrating in a direction parallel to the second polarization axis and may block light vibrating in a direction not parallel to the second polarization axis.

In one or more embodiments, the second polarizing film 825 may be a reflective polarizing film. In this regard, the second polarizing film 825 may pass light vibrating in a direction parallel to the second polarization axis and may reflect light vibrating in a direction not parallel to the second polarization axis.

The third polarizing film 826 may be located on the second polarizing film 825. The third polarizing film 826 may have a third polarization axis extending in one direction. The third polarizing film 826 may be a linear polarizing film. The third polarizing film 826 may linearly polarize light in the direction of the third polarization axis. For example, the third polarizing film 826 may pass light vibrating in a direction parallel to the third polarization axis and may block light vibrating in a direction not parallel to the third polarization axis. In one or more embodiments, the third polarizing film 826 may not be provided.

In one or more embodiments, the third polarizing film 826 may be an absorption-type (kind) polarizing film. In this regard, the third polarizing film 826 may pass light vibrating in a direction parallel to the third polarization axis and may be to absorb light vibrating in a direction not parallel to the third polarization axis.

The second coating film AR2 may be located on the second surface TPLb of the optical array module TPL. For example, in one or more embodiments, the second coating film AR2 may be located on the third lens 831. The second coating film AR2 may be an anti-reflection film. The second coating film AR2 may be formed by anti-reflection coating. The second coating film AR2 may prevent or reduce light passing through a top surface (left side in the drawing) of the optical array module TPL from being reflected. Accordingly, the light output efficiency may be improved, and the occurrence of stray light may be minimized or reduced.

In one or more embodiments, at least one of the first coating film AR1 or the second coating film AR2 may not be provided depending on the degree of improvement in transmittance and reflectivity of each member.

The display device 10 according to one or more embodiments may implement folded optics that folds the optical path by including the optical module 800_1. Accordingly, a total track length, which is the total length of the optical path, may be increased while concurrently (e.g., simultaneously) minimizing or reducing the thickness of the display device 10.

In the display device 10 according to one or more embodiments, similar to the display device 10 according to the embodiments described with reference to FIG. 10 and/or the like, the reflection control film 821 may include a first portion 821a and a second portion 821b. Accordingly, the luminous efficiency may be increased.

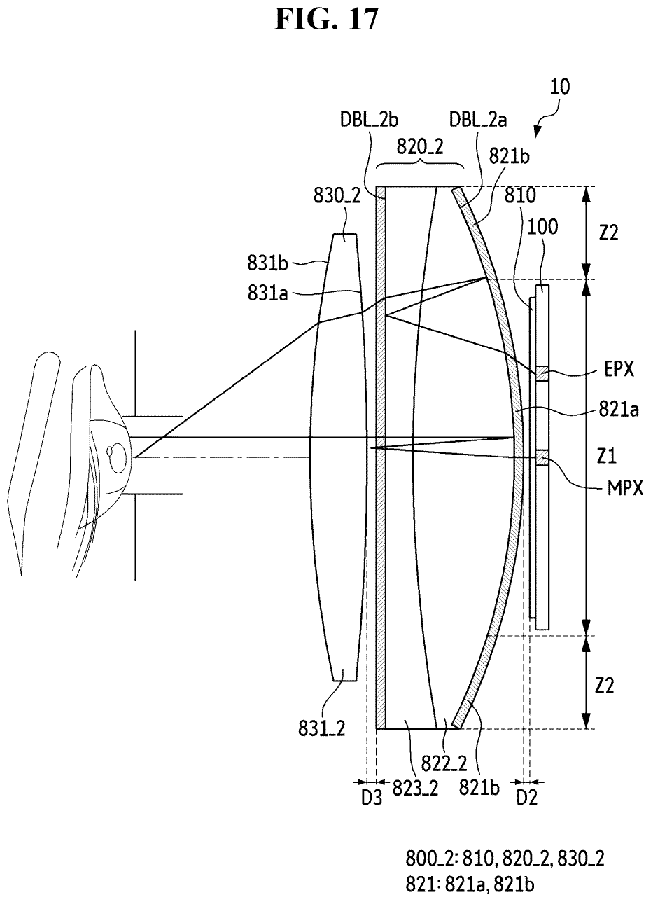

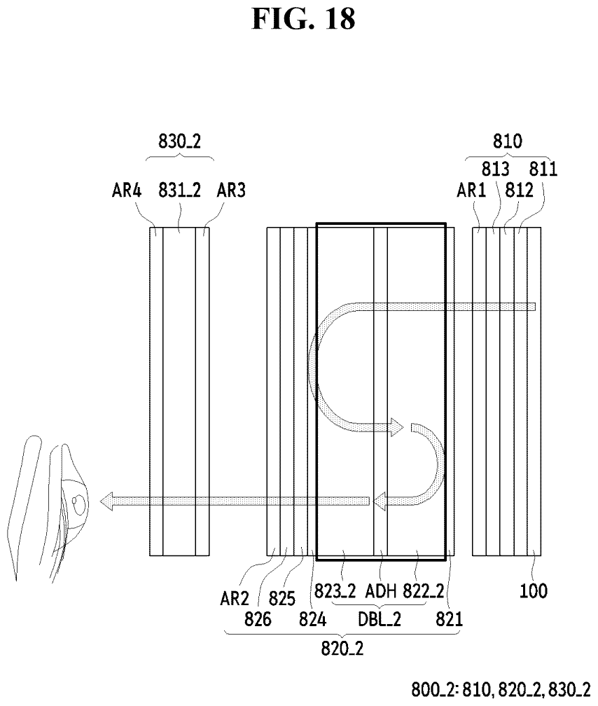

FIGS. 17 and 18 are cross-sectional views showing a display device according to one or more embodiments of the present disclosure.

Referring to FIGS. 17 and 18, the display device 10 according to one or more embodiments is different from the display device according to the embodiments described above with reference to FIG. 15 and/or the like in that the display device is a doublet lens instead of a triplet lens.

For example, an optical module 800_2 may include a first optical module 810, a second optical module 820_2, and a third optical module 830_2. The first optical module 810 may be located on the display panel 100, the second optical module 820_2 may be located on the first optical module 810, and the third optical module 830_2 may be located on the second optical module 820_2.

In one or more embodiments, the second optical module 820_2 may be spaced and/or apart (e.g., spaced apart or separated) from the first optical module 810 by a second distance D2, and the third optical module 830_2 may be spaced and/or apart (e.g., spaced apart or separated) from the second optical module 820_2 by a third distance D3. An air gap filled with a gas (e.g., air) may be positioned each between the second optical module 820_2 and the first optical module 810 and between the third optical module 830_2 and the second optical module 820_2.

The second optical module 820_2 may include a reflection control film 821, a first lens DBL_2, a third phase retardation film 824, a second polarizing film 825, a third polarizing film 826, and a second coating film AR2. The third optical module 830_2 may include a second lens 831_2, a third coating film AR3, and a fourth coating film AR4. The first lens DBL_2 of the second optical module 820_2 may include a first sub-lens 822_2 and a second sub-lens 823_2.

The first lens DBL_2 may be located on the first optical module 810. For example, the first lens DBL_2 may be located on the first coating film AR1 of the first optical module 810. The first lens DBL_2 may be spaced and/or apart (e.g., spaced apart or separated) from the first optical module 810. The first lens DBL_2 may magnify an image formed by light generated from the display panel 100.

The first lens DBL_2 may be a doublet lens. For example, the first lens DBL_2 may be a lens in which the first sub-lens 822_2 and the second sub-lens 823_2 are combined. An adhesive layer ADH may be located between the first sub-lens 822_2 and the second sub-lens 823_2. The first sub-lens 822_2 and the second sub-lens 823_2 may be combined by the adhesive layer ADH.

The display device 10 according to one or more embodiments may reduce the thickness of the optical module 800_2 by including a doublet lens. Accordingly, it may become easier to ensure the optimal or suitable distance for eye relief. Additionally, the field of view (FOV) may be increased through aberration correction and focus correction by using a doublet lens. Further, because the doublet lens is included, an air gap located between separate lenses spaced apart from each other may be eliminated, and light loss due to reflection at the interface between the air gap and the lens may be minimized or reduced, thereby increasing light efficiency.

In one or more embodiments, the average curvatures of a first surface DBL_2a and a second surface DBL_2b of the first lens DBL_2 may be different. For example, the average curvature of the first surface DBL_2a of the first lens DBL_2 may be greater than the average curvature of the second surface DBL_2b. In one or more embodiments, the first surface DBL_2a of the first lens DBL_2 may be an aspherical surface including multiple curvatures, and the second surface DBL_2b may be a flat surface, but embodiments of the present disclosure are not limited thereto. The first surface DBL_2a of the first lens DBL_2 may be a surface opposite to (e.g., facing) the first optical module 810, and the second surface DBL_2b may be a surface opposite to (e.g., facing) the third optical module 830_2.

In the display device 10 according to one or more embodiments, the first lens DBL_2 may include an aspherical surface, so that the color crosstalk (or color X-talk) phenomenon may be mitigated. In addition, as described above with reference to FIG. 9, by adjusting the first distance D1 that is the degree to which the plurality of sub-pixels SP1, SP2, and SP3 are shifted with respect to the plurality of corresponding lenses LNS in the direction from the middle pixel MPX to the edge pixel EPX and concurrently (e.g., simultaneously) adjusting each of the plurality of curvatures of the aspherical surface of the first lens DBL_2, the average luminance amount according to the chief ray array (CRA) angle distribution may be further improved.

The reflection control film 821 may be located on the first surface DBL_2a of the first lens DBL_2. The reflection control film 821 may be located between the first lens DBL_2 and the first optical module 810. The reflection control film 821 may be to transmit part of incident light and reflect the remaining part. For example, the reflection control film 821 may include a half mirror.

Light transmitted through the reflection control film 821 may be transmitted without phase change. Light reflected from the reflection control film 821 may be reflected with its phase reversed. For example, left-circularly polarized light may be reflected from the reflection control film 821 to be right-circularly polarized light, and the right-circularly polarized light may be reflected from the reflection control film 821 to be left-circularly polarized light.

The reflection control film 821 may be conformally formed according to a shape of the first surface DBL_2a of the first lens DBL_2. Because the first surface DBL_2a of the first lens DBL_2 is an aspherical surface including a plurality of curvatures, the viewing angle and the magnification ratio may be increased. Accordingly, the number of components of the optical module 800_2 may be reduced and the thickness of the display device 10 may be reduced.

The third phase retardation film 824 may be located on the second surface DBL_2b of the first lens DBL_2.

The second coating film AR2 may be located on the third polarizing film 826. The second coating film AR2 may be an anti-reflection film. The second coating film AR2 may be formed by anti-reflection coating. The second coating film AR2 may prevent or reduce light passing through the second surface DBL_2b of the first lens DBL_2 from being reflected. Accordingly, the light output efficiency may be improved, and the occurrence of stray light may be minimized or reduced.

The second lens 831_2 may be located on the second optical module 820_2. For example, in one or more embodiments, the second lens 831_2 may be located on the second coating film AR2 of the second optical module 820_2. The second lens 831_2 may be spaced and/or apart (e.g., spaced apart or separated) from the second optical module 820_2. The second lens 831_2 may magnify an image formed by light generated from the display panel 100.

The second lens 831_2 may be a single lens. The second lens 831_2 may be a magnifying lens. In one or more embodiments, the second lens 831_2 may include at least one of a convex lens, a meniscus lens, or a Fresnel lens.

In one or more embodiments, the average curvatures of a first surface 831a and a second surface 831b of the second lens 831_2 may be different. For example, the average curvature of the first surface 831a of the second lens 831_2 may be smaller than the average curvature of the second surface 831b of the second lens 831_2. In one or more embodiments, the first surface 831a and the second surface 831b of the second lens 831_2 may each be an aspherical surface including a plurality of curvatures. The first surface 831a of the second lens 831_2 may be a surface opposite to (e.g., facing) the second optical module 820_2, and the second surface 831b may be a surface located on the opposite side of the first surface 831a.

In the display device 10 according to one or more embodiments, the second lens 831_2 may include an aspherical surface, so that the color crosstalk (or color X-talk) phenomenon may be mitigated. In addition, as described above with reference to FIG. 9, by adjusting the first distance D1 that is the degree to which the plurality of sub-pixels SP1, SP2, and SP3 are shifted with respect to the plurality of corresponding lenses LNS in the direction from the middle pixel MPX to the edge pixel EPX and concurrently (e.g., simultaneously) adjusting each of the plurality of curvatures of the aspherical surface of the second lens 831_2, the average luminance amount according to the chief ray array (CRA) angle distribution may be further improved.

The third coating film AR3 and the fourth coating film AR4 may be located on the second lens 831_2. For example, the third coating film AR3 may be located on the first surface 831a of the second lens 831_2, and the fourth coating film AR4 may be located on the second surface 831b of the second lens 831_2. The third coating film AR3 and the fourth coating film AR4 may be each an anti-reflection film. The third coating film AR3 and the fourth coating film AR4 may each be formed by anti-reflection coating. The third coating film AR3 and the fourth coating film AR4 may prevent or reduce light passing through the first surface 831a and the second surface 831b of the second lens 831_2 from being reflected. Accordingly, the light output efficiency may be improved, and the occurrence of stray light may be minimized or reduced.

In one or more embodiments, at least one of the first coating film AR1, the second coating film AR2, the third coating film AR3, or the fourth coating film AR4 may not be provided depending on the degree of improvement in transmittance and reflectivity of each member.

The display device 10 according to one or more embodiments may implement folded optics that folds the optical path by including the optical module 800_2. Accordingly, a total track length, which is the total length of the optical path, may be increased while concurrently (e.g., simultaneously) minimizing or reducing the thickness of the display device 10.

In the display device 10 according to one or more embodiments, similar to the display device 10 according to the embodiments described with reference to FIG. 10 and/or the like, the reflection control film 821 may include a first portion 821a and a second portion 821b. Accordingly, the luminous efficiency may be increased.

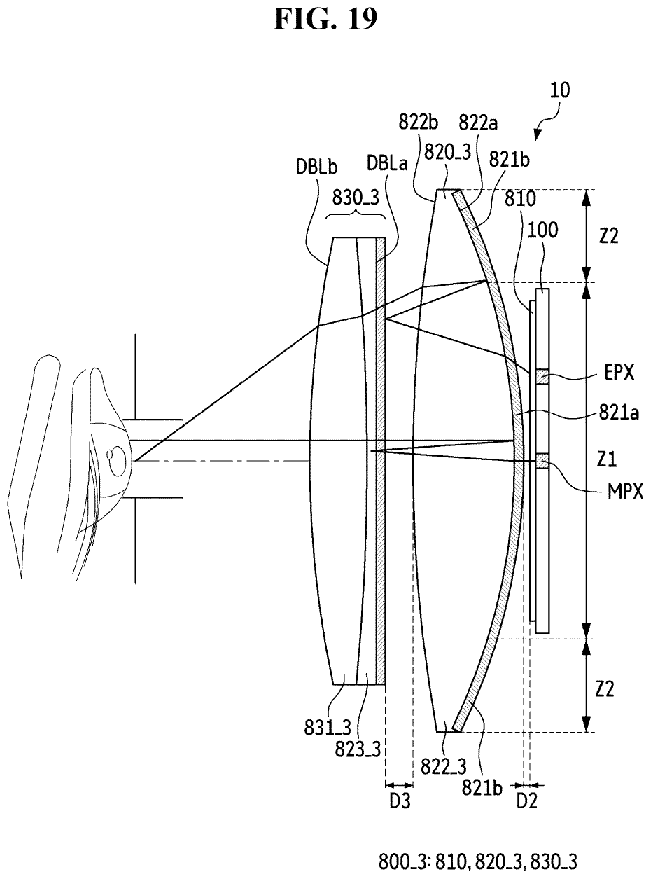

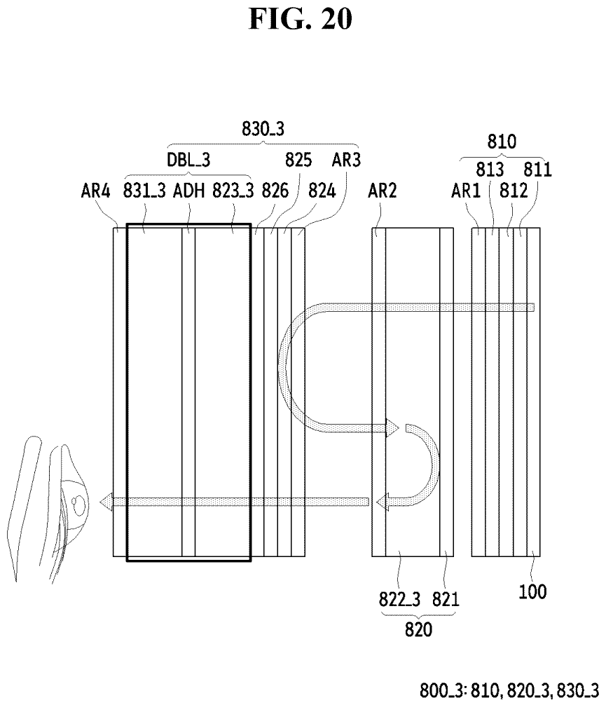

FIGS. 19 and 20 are sectional views showing a display device according to one or more embodiments of the present disclosure.

Referring to FIGS. 19 and 20, the display device 10 according to one or more embodiments is different from the display device 10 according to the embodiments described with reference to FIG. 17 and/or the like in that a third optical module 830_3 includes a doublet lens.

For example, a second optical module 820_3 may include a reflection control film 821, a first lens 822_3, and a second coating film AR2. The third optical module 830_3 may include a third coating film AR3, a third phase retardation film 824, a second polarizing film 825, a third polarizing film 826, a second lens DBL_3, and a fourth coating film AR4. The second lens DBL_3 of the third optical module 830_3 may include a first sub-lens 831_3 and a second sub-lens 823_3.

The first lens 822_3 may be located on the first optical module 810. For example, in one or more embodiments, the first lens 822_3 may be located on the first coating film AR1 of the first optical module 810. The first lens 822_3 may be spaced and/or apart (e.g., spaced apart or separated) from the first optical module 810. The first lens 822_3 may magnify an image formed by light generated from the display panel 100.

The first lens 822_3 may be a single lens. The first lens 822_3 may be a magnifying lens. In one or more embodiments, the first lens 822_3 may include at least one of a convex lens, a meniscus lens, or a Fresnel lens.

In one or more embodiments, the average curvatures of a first surface 822a and a second surface 822b of the first lens 822_3 may be different. For example, the average curvature of the first surface 822a of the first lens 822_3 may be greater than the average curvature of the second surface 822b of the first lens 822_3. In one or more embodiments, the first surface 822a and the second surface 822b of the first lens 822_3 may each be an aspherical surface including a plurality of curvatures. The first surface 822a of the first lens 822_3 may be a surface opposite to (e.g., facing) the first optical module 810, and the second surface 822b may be a surface opposite to (e.g., facing) the third optical module 830_3.

In the display device 10 according to one or more embodiments, the first lens 822_3 may include an aspherical surface, so that the color crosstalk (or color X-talk) phenomenon may be mitigated. In addition, as described above with reference to FIG. 9, by adjusting the first distance D1 that is the degree to which the plurality of sub-pixels SP1, SP2, and SP3 are shifted with respect to the plurality of corresponding lenses LNS in the direction from the middle pixel MPX to the edge pixel EPX and concurrently (e.g., simultaneously) adjusting each of the plurality of curvatures of the aspherical surface of the first lens 822_3, the average luminance amount according to the chief ray array (CRA) angle distribution may be further improved.

The reflection control film 821 may be located on the first surface 822a of the first lens 822_3. The reflection control film 821 may be located between the first lens 822_3 and the first optical module 810. The reflection control film 821 may be to transmit part of incident light and reflect the remaining part. For example, the reflection control film 821 may include a half mirror.

Light transmitted through the reflection control film 821 may be transmitted without phase change. Light reflected from the reflection control film 821 may be reflected with its phase reversed. For example, left-circularly polarized light may be reflected from the reflection control film 821 to be right-circularly polarized light, and the right-circularly polarized light may be reflected from the reflection control film 821 to be left-circularly polarized light.

The reflection control film 821 may be conformally formed according to a shape of the first surface 822a of the first lens 822_3. Because the first surface 822a of the first lens 822_3 is an aspherical surface including a plurality of curvatures, the viewing angle and the magnification ratio may be increased. Accordingly, the number of components of an optical module 800_3 may be reduced and the thickness of the display device 10 may be reduced.

The second coating film AR2 may be located on the second surface 822b of the first lens 822_3. The second coating film AR2 may be an anti-reflection film. The second coating film AR2 may be formed by anti-reflection coating. The second coating film AR2 prevent or reduce light passing through the second surface 822b of the first lens 822_3 from being reflected. Accordingly, the light output efficiency may be improved, and the occurrence of stray light may be minimized or reduced.

The second lens DBL_3 may be located on the second optical module 820_3. For example, in one or more embodiments, the second lens DBL_3 may be located on the second coating film AR2. The second lens DBL_3 may be spaced and/or apart (e.g., spaced apart or separated) from the second optical module 820_3. The second lens DBL_3 may magnify an image formed by light generated from the display panel 100.

The second lens DBL_3 may be a doublet lens. For example, the second lens DBL_3 may be a lens in which the first sub-lens 831_3 and the second sub-lens 823_3 are combined. An adhesive layer ADH may be located between the first sub-lens 831_3 and the second sub-lens 823_3. The first sub-lens 831_3 and the second sub-lens 823_3 may be combined by the adhesive layer ADH.

The display device 10 according to one or more embodiments may reduce the thickness of the optical module 800_3 by including a doublet lens. Accordingly, it may become easier to ensure the optimal or suitable distance for eye relief. Additionally, the field of view (FOV) may be increased through aberration correction and focus correction by using a doublet lens. Further, because the doublet lens is included, an air gap located between separate lenses spaced apart from each other may be eliminated, and light loss due to reflection at the interface between the air gap and the lens may be minimized or reduced, thereby increasing light efficiency.

In one or more embodiments, the average curvatures of a first surface DBLa and a second surface DBLb of the second lens DBL_3 may be different. For example, the average curvature of the first surface DBLa of the second lens DBL_3 may be smaller than the average curvature of the second surface DBLb. In one or more embodiments, the first surface DBLa of the second lens DBL_3 may be a flat surface, and the second surface DBLb may be an aspherical surface including a plurality of curvatures, but embodiments of the present disclosure are not limited thereto. The first surface DBLa of the second lens DBL_3 may be a surface opposite to (e.g., facing) the second optical module 820_3, and the second surface DBLb may be a surface located on the opposite side of the first surface DBLa.

In the display device 10 according to one or more embodiments, the second lens DBL_3 may include an aspherical surface, so that the color crosstalk (or color X-talk) phenomenon may be mitigated. In addition, as described above with reference to FIG. 9, by adjusting the first distance D1 that is the degree to which the plurality of sub-pixels SP1, SP2, and SP3 are shifted with respect to the plurality of corresponding lenses LNS in the direction from the middle pixel MPX to the edge pixel EPX and concurrently (e.g., simultaneously) adjusting each of the plurality of curvatures of the aspherical surface of the second lens DBL_3, the average luminance amount according to the chief ray array (CRA) angle distribution may be further improved.

The third phase retardation film 824, the second polarizing film 825, and the third polarizing film 826 may be located on the first surface DBLa of the second lens DBL_3.

The third coating film AR3 may be located on the third phase retardation film 824. The third coating film AR3 may be an anti-reflection film. The third coating film AR3 may be formed by anti-reflection coating. The third coating film AR3 may prevent or reduce light passing through the first surface DBLa of the second lens DBL_3 from being reflected. Accordingly, the light output efficiency may be improved, and the occurrence of stray light may be minimized or reduced.

The fourth coating film AR4 may be located on the second surface DBLb of the second lens DBL_3. The fourth coating film AR4 may be an anti-reflection film. The fourth coating film AR4 may be formed by anti-reflection coating. The fourth coating film AR4 may be prevent or reduce light passing through the second surface DBLb of the second lens DBL_3 from being reflected. Accordingly, the light output efficiency may be improved, and the occurrence of stray light may be minimized or reduced.

The display device 10 according to one or more embodiments may implement folded optics that folds the optical path by including the optical module 800_3. Accordingly, a total track length, which is the total length of the optical path, may be increased while concurrently (e.g., simultaneously) minimizing or reducing the thickness of the display device 10.

In the display device 10 according to one or more embodiments, similar to the display device 10 according to the embodiments described with reference to FIG. 10 and/or the like, the reflection control film 821 may include a first portion 821a and a second portion 821b. Accordingly, the light efficiency may be increased.

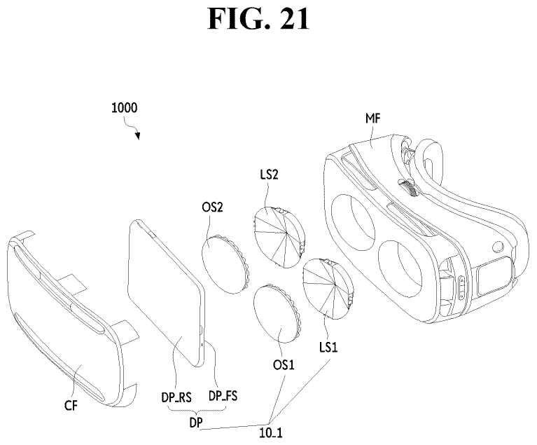

FIG. 21 is an exploded perspective view illustrating a head mounted display according to one or more embodiments of the present disclosure.

Referring to FIG. 21, a head mounted display 1000 may be formed in the form of glasses or a head mount to provide an image to a user using a display device 10_1.

The head mounted display 1000 may include a see-through type (kind) that provides augmented reality based on actual external objects and a see-closed type (kind) that provides virtual reality to the user on a screen independent from external objects.

The head mounted display 1000 may include a main frame MF mounted on the user's body, the display device 10_1 mounted on the main frame MF to display an image, and a cover frame CF that covers the display device 10_1.

The display device 10_1 may be formed integrally with the head mounted display 1000 that may be carried by the user and easily attached to or detached from the face or the head of the user, and may be formed to be assembled to the head mounted display 1000. The display device 10_1 may be substantially the same as the display device 10 described in conjunction with FIG. 1 and/or the like.

The display device 10_1 may include a display panel DP that displays an image, first and second lens frames OS1 and OS2 that refract image display light, and first and second multi-channel lenses LS1 and LS2 that form an optical path so that the image display light of the display panel DP is visible to the user.

The main frame MF may be worn on the user's face and head. The main frame MF may be formed in a shape corresponding to the user's head and facial structure.

In one or more embodiments, the main frame MF may be integrally formed with display device 10_1, that is, the display panel DP, the first and second lens frames OS1 and OS2, and the first and second multi-channel lenses LS1 and LS2. In one or more embodiments, the display panel DP, the first and second lens frames OS1 and OS2, and the first and second multi-channel lenses LS1 and LS2 may be assembled and mounted to the main frame MF. To this end, the main frame MF may have a space or a structure for accommodating the display panel DP, the first and second lens frames OS1 and OS2, and the first and second multi-channel lenses LS1 and LS2. The main frame MF may further include a structure such as a strap or a band to facilitate the mounting, and a controller, an image processing unit, and a lens accommodating unit may be further included in the main frame MF.

The display panel DP may be divided into a front surface DP_FS where an image is displayed, and a rear surface DP_RS positioned on the opposite side of the front surface DP_FS. Image display light may be emitted from the front surface DP_FS of the display panel DP. As will be described later, the first and second lens frames OS1 and OS2 may be located on the front surface DP_FS of the display panel DP, and the first and second multi-channel lenses LS1 and LS2 may be located on front surfaces of the first and second lens frames OS1 and OS2. In one or more embodiments, at least one infrared camera may be located on at least one of the front surface DP_FS or the rear surface DP_RS of the display panel DP. The display panel DP may be substantially the same as the display panel 100 described in conjunction with FIG. 1 and/or the like.

The display panel DP may be built in the main frame MF in a state where the first and second lens frames OS1 and OS2 and the first and second multi-channel lenses LS1 and LS2 are mounted and fixed, or may be detachably assembled to the main frame MF. The display panel DP may be opaque, transparent, or translucent depending on the design of the display device 10_1, for example, the usage type (kind) of the display device 10_1.

Each of the first and second lens frames OS1 and OS2 may have an area corresponding to an image display surface of the display panel DP, and may be formed in a shape corresponding to that of the image display surface. Further, the first and second lens frames OS1 and OS2 may be formed to have an area and a shape corresponding to those of rear surfaces of the first and second multi-channel lenses LS1 and LS2, respectively. Rear surfaces of the first and second lens frames OS1 and OS2 may be attached to the image display surface of the display panel DP, and the first and second multi-channel lenses LS1 and LS2 may be attached to front surfaces of the first and second lens frames OS1 and OS2, respectively. The first and second lens frames OS1 and OS2 refract the image display light emitted from the image display surface of the display panel DP at a preset angle and provide it to the first and second multi-channel lenses LS1 and LS2 located on the front surfaces thereof, respectively.

For example, the first and second lens frames OS1 and OS2 may refract the image display light, which is emitted from the image display surface of the display panel DP toward the front side, toward an outer side (or toward an outer peripheral side) compared to the front side and provide it to the first and second multi-channel lenses LS1 and LS2 located on the front surfaces thereof, respectively. For example, the first and second lens frames OS1 and OS2 may refract the image display light incident on the rear surfaces thereof toward the outer side (or toward the outer peripheral side) and provide it to the rear surfaces of the first and second multi-channel lenses LS1 and LS2, respectively.

The first and second multi-channel lenses LS1 and LS2 may form a path for light emitted through the first and second lens frames OS1 and OS2, so that the image display light is visible to the user's eyes on the front side (i.e., the side toward the user).

The first and second multi-channel lenses LS1 and LS2 may provide a plurality of channels (or paths) through which the image display light emitted from the display panel DP passes. The plurality of channels may provide the image display light emitted from the display panel DP to the user through different paths. The image display light emitted through the first and second lens frames OS1 and OS2 may be incident on the respective channels, and the image magnified through the respective channels may be focused on the user's eyes.

The first and second multi-channel lenses LS1 and LS2 may be respectively arranged on the front surfaces the first and second lens frames OS1 and OS2 to correspond to the positions of the user's left eye and right eye. The first and second multi-channel lenses LS1 and LS2 may be accommodated in the main frame MF.

The first and second multi-channel lenses LS1 and LS2 may refract and/or reflect the image display light emitted through the first and second lens frames OS1 and OS2 at least once to form a path to the user's eyes. At least one infrared light source may be further located at the main frame MF, or on one side of each of the first and second multi-channel lenses LS1 and LS2 opposite to (e.g., facing) the use's eyes.

The cover frame CF may be located on the rear surface DP_RS of the display panel DP to cover the display panel DP and may protect the display panel DP. The cover frame CF may be attached to the main frame MF while covering the display panel DP.

In one or more embodiments, the display device 10_1 may further include a controller for controlling the overall operation of the display device 10_1 including the display panel DP. The controller may control the image display operation of the display panel DP and audio devices. For example, the controller performs image processing (e.g., image mapping) according to the magnification ratio and the image display path corresponding to the first and second lens frames OS1 and OS2 and the first and second multi-channel lenses LS1 and LS2, and controls the mapped image to be displayed on the display panel DP. The controller may be implemented as a dedicated processor including an embedded processor and/or a general-purpose processor including a central processing unit or an application processor, but embodiments of the present disclosure are not limited thereto.

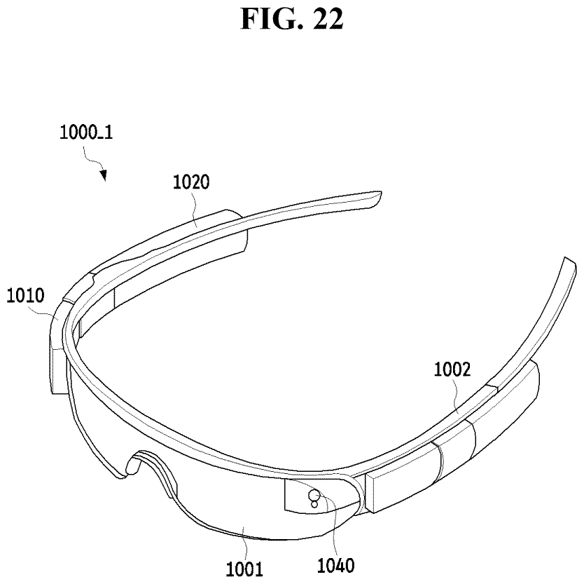

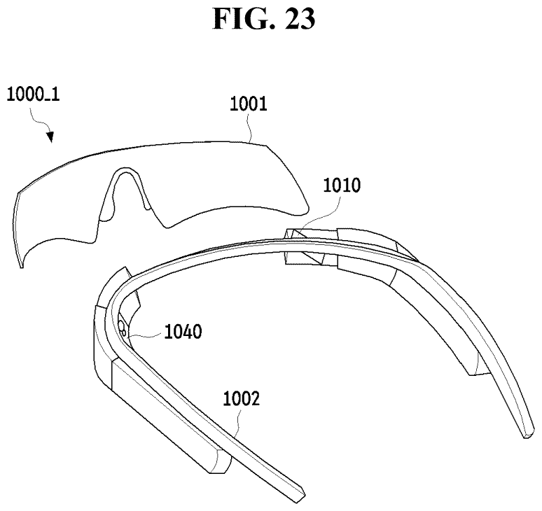

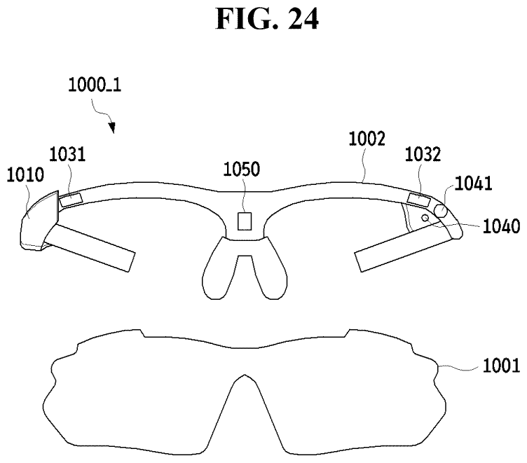

FIG. 22 is a perspective view showing an augmented reality content providing device according to one or more embodiments of the present disclosure. FIG. 23 is a rear exploded perspective view of the augmented reality content providing device of FIG. 22 according to one or more embodiments. FIG. 24 is a front exploded perspective view of the augmented reality content providing device of FIG. 22 according to one or more embodiments.

Referring to FIGS. 22 to 24, an augmented reality content providing device 1000_1 may include a support frame 1002 supporting at least one transparent lens 1001, at least one image display module 1010, a surrounding environment detector 1040, and a control module 1020.

The support frame 1002 may be in the form of glasses including a spectacle frame supporting an edge of at least one transparent lens 1001 and spectacle frame legs. A shape of the support frame 1002 is not limited to a glasses type (kind), and may be formed in a goggle type (kind) including the transparent lens 1001, or a head mounted type (kind).

The transparent lens 1001 may include left and right parts formed integrally, or first and second transparent lenses formed separately. The transparent lens 1001, which includes the integrated left and right parts or the separated first and second transparent lenses, may include glass or plastic (e.g., a polymer material) that is transparent or translucent. Accordingly, a user may view an image of reality through the transparent lens 1001 that includes the integrated right and left parts or the separated first and second transparent lenses. Here, the transparent lens 1001, that is, the integrated lens or the first and second transparent lenses, may have a refractive power in consideration of the user's eyesight.

The transparent lens 1001 may further include at least one reflective member that reflects an augmented reality content image provided from the at least one image display module 1010 toward the transparent lens 1001 or the user's eyes, and optical members that adjust a focus and a size. One or more reflective member may be built in the transparent lens 1001 to be integrated with the transparent lens 1001, and may be formed as a plurality of refractive lenses or a plurality of prisms with a selected curvature.

The at least one image display module 1010 may include a micro LED display device (micro-LED), a nano LED display device (nano-LED), an organic light emitting display device (OLED), an inorganic light emitting display device (inorganic EL), a quantum dot light emitting display device (QED), a cathode ray display (CRT), a liquid crystal display (LCD), and/or the like. The at least one image display module 1010 may substantially include the display device 10 described with reference to FIG. 1 and/or the like.

The surrounding environment detector 1040 is assembled or integrally formed with the support frame 1002, and detects the distance (or depth) to an object on a front side of the support frame 1002, the illuminance, the moving direction of the support frame 1002, the moving distance, the tilt, and/or the like. To this end, the surrounding environment detector 1040 may include a depth sensor 1041 such as an infrared sensor or a LiDAR sensor, and an image sensor 1050 such as a camera. In one or more embodiments, the surrounding environment detector 1040 may further include at least one motion sensor selected from among an illumination sensor, a human body detection sensor, a gyro sensor, a tilt sensor, and an acceleration sensor. In one or more embodiments, the surrounding environment detector 1040 may further include first and second biometric sensors 1031 and 1032 for detecting movement information of the user's eyes or pupils.

The surrounding environment detector 1040 may be to transmit sensing signals generated by the depth sensor 1041 and the at least one motion sensor to the control module 1020 in real time. Further, the image sensor 1050 may be to transmit image data in units of at least one frame generated in real time to the control module 1020. The first and second biometric sensors 1031 and 1032 of the surrounding environment detector 1040 may be to transmit detected pupil detection signals to the control module 1020.

The control module 1020 may be assembled to at least one side of the support frame 1002 together with the at least one image display module 1010 or may be formed integrally with the support frame 1002. The control module 1020 supplies augmented reality content data to the at least one image display module 1010 so that the at least one image display module 1010 displays an augmented reality content, e.g., an augmented reality content image. At the same time, the control module 1020 may receive sensing signals, image data, and pupil detection signals from the surrounding environment detector 1040 in real time.

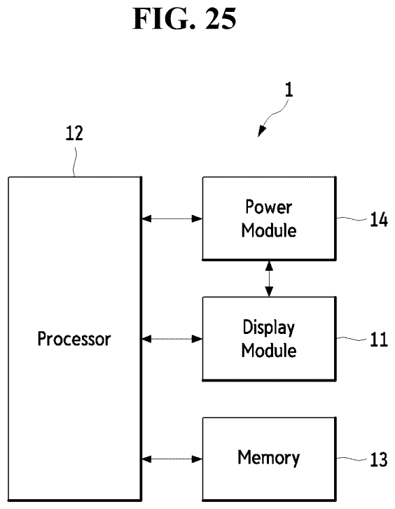

In one or more embodiments, the display device 10 according to the above-described embodiments may be applied to one or more suitable electronic devices 1 (see FIG. 25), in addition to the head mounted display 1000 and the augmented reality content (e.g., amount) providing device 1000_1 described above. An electronic device 1 (see FIG. 25) according to one or more embodiments may include the above-described display device 10, and may further include, in addition to the display device 10, a module or device having other additional functions.

FIG. 25 is a block diagram of an electronic device according to one or more embodiments of the present disclosure.

Referring to FIG. 25, the electronic device 1 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information desired or required for an operation of the processor 12 and/or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power desired or required for the operation of the electronic device 1.

At least one of the components of the electronic device 1 described above may be included in the display device 10 according to the embodiments described above. Further, some of individual modules functionally included in one module may be included in the display device 10 and some others may be provided separately from the display device 10. For example, the display device 10 may include the display module 11, and the processor 12, the memory 13, and the power module 14 may be provided in the form of other devices in the electronic device 1 other than the display device 10.

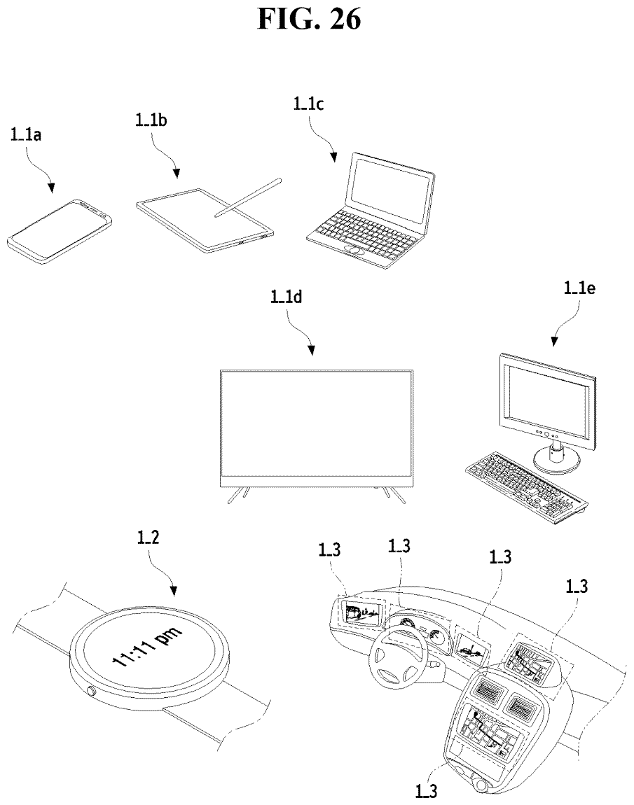

FIG. 26 is a schematic view illustrating electronic devices according to various embodiments of the present disclosure.

Referring to FIG. 26, one or more suitable electronic devices to which the display device 10 according to one or more embodiments is applied may include not only an image display electronic device such as a smartphone 1_1a, a tablet PC 1_1b, a laptop 1_1c, a TV 1_1d, and a desk monitor 1_1e, but also a wearable electronic device including a display module, such as a smart watch 1_2, and/or the like, vehicle electronic devices 1_3 including a display module, such as a center fascia, and a dashboard of an automobile, a center information display (CID) placed on the dashboard, a room mirror display, and/or the like.

In the present disclosure, it will be understood that the terms “comprise(s)/comprising,” “include(s)/including,” or “have/has/having” specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light emitting element, the display module, the display panel, the display device, the electronic device/apparatus, the device-manufacturing apparatus, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In concluding the detailed description, those skilled in the art will appreciate that many variations and modifications may be made to the presented embodiments without substantially departing from the principles of the present disclosure. Therefore, the disclosed embodiments of the present disclosure are used in a generic and descriptive sense only and not for purposes of limitation. It is to be understood that the scope of the present disclosure is defined by the appended claims and equivalents thereof rather than the detailed description described above, and all modifications and alterations derived from the claims and their equivalents fall within the scope of the present disclosure.

What is claimed is:

1. A display device, comprising:
a display panel;
a first polarizing film on the display panel;
a first phase retardation film on the first polarizing film;
a reflection control film on the first phase retardation film;
a first lens on the reflection control film;
a second lens on the first lens;
a second phase retardation film on the second lens;
a second polarizing film on the second phase retardation film; and
a third lens on the second polarizing film,
wherein the reflection control film comprises:
a first portion; and
a second portion located at a periphery of the first portion, and
wherein a reflectivity of the first portion is different from a reflectivity of the second portion.

2. The display device of claim 1,
wherein the reflectivity of the second portion is greater than the reflectivity of the first portion.

3. The display device of claim 2,
wherein the reflectivity of the first portion is 47% to 53%, and the reflectivity of the second portion is 80% or more.

4. The display device of claim 1,
wherein the first portion comprises a half mirror, and
wherein the second portion comprises a regular mirror.

5. The display device of claim 1,
wherein the first portion comprises multilayer films in which low-refractive index films and high-refractive index films are alternately stacked.

6. The display device of claim 5,
wherein the low-refractive index film comprises at least one of silicon oxide or silicon oxynitride.

7. The display device of claim 5,
wherein the high-refractive index film comprises at least one of silicon nitride or titanium oxide.

8. The display device of claim 1,
wherein the second portion comprises a substrate and a reflective layer comprising a metal material.

9. The display device of claim 1,
wherein the first portion is configured to transmit and reflect light generated from the display panel, and
wherein the second portion is configured to reflect light generated from the display panel.

10. The display device of claim 1,
wherein the first lens, the second lens, and the third lens are spaced from one another.

11. The display device of claim 10,
further comprising at least one anti-reflection coating film between the first lens and the second lens, and/or between the second lens and the third lens.

12. The display device of claim 1,
wherein the first lens, the second lens, and the third lens are combined to form a triplet lens, and
wherein the display device further comprises:
a first adhesive layer between the first lens and the second lens; and
a second adhesive layer between the second lens and the third lens.

13. The display device of claim 1,
wherein the first lens and the second lens are combined to form a doublet lens, and
wherein the doublet lens and the third lens are spaced from each other.

14. The display device of claim 13,
further comprising:
an adhesive layer between the first lens and the second lens; and
at least one anti-reflection coating film between the doublet lens and the third lens.

15. The display device of claim 1,
wherein the second lens and the third lens are combined to form a doublet lens, and
wherein the doublet lens and the first lens are spaced from each other.

16. The display device of claim 15,
further comprising:
an adhesive layer between the second lens and the third lens; and
at least one anti-reflection coating film between the doublet lens and the first lens.

17. The display device of claim 1,
wherein the reflection control film is on a first surface of the first lens, and
wherein the first surface of the first lens is an aspherical surface.

18. The display device of claim 1,
wherein each of the first lens, the second lens, and the third lens is a magnifying lens.

19. An electronic device comprising:
a display device; and
a processor to provide a signal to the display device, wherein the display device comprises:
a display panel;
a first polarizing film on the display panel;
a first phase retardation film on the first polarizing film;
a reflection control film on the first phase retardation film;
a first lens on the reflection control film;
a second lens on the first lens;
a second phase retardation film on the second lens;
a second polarizing film on the second phase retardation film; and
a third lens on the second polarizing film,
wherein the reflection control film comprises:
a first portion; and
a second portion located at a periphery of the first portion, and
wherein a reflectivity of the first portion is different from a reflectivity of the second portion.

20. The electronic device of claim 19,
wherein the reflection control film is on a first surface of the first lens, and
wherein the first surface of the first lens is an aspherical surface.
